(19) United States
(12) Patent Application Publication
(10) Pub. No.: US 2020/0126819 A1
(43) Pub. Date: Apr. 23, 2020

(54) JOINED COMPONENT THROUGH WHICH PROCESS FLUID PASSES IN SEMICONDUCTOR MANUFACTURING PROCESS OR DISPLAY MANUFACTURING PROCESS

(71) Applicant: Bum Mo Ahn, Suwon (KR)

(72) Inventor: Bum Mo Ahn, Suwon (KR)

(21) Appl. No.: 16/659,125

(22) Filed: Oct. 21, 2019

(30) Foreign Application Priority Data
Oct. 23, 2018 (KR) 10-2018-0126715

(51) Int. Cl. H01L 21/67; G02F 1/13; B23K 20/12

(52) U.S. Cl. CPC H01L 21/67017; B23K 2101/20; B23K 20/122; G02F 1/1303

(57) ABSTRACT

Disclosed is a joined component that is formed by joining parent members by friction stir welding.

### CROSS REFERENCE TO RELATED APPLICATION

The present application claims priority to Korean Patent Application No. 10-2018-0126715, filed Oct. 23, 2018, the entire contents of which is incorporated herein for all purposes by this reference.

### BACKGROUND OF THE INVENTION

### Field of the Invention

The present invention relates to a joined component that is formed by friction stir welding and through which a process fluid passes in a semiconductor manufacturing process or a display manufacturing process.

### Description of the Related Art

As a technique for depositing a thin film on a semiconductor substrate or glass, chemical vapor deposition (CVD) or atomic layer deposition (ALD), which are thin-film deposition techniques based on chemical reaction, is used. Equipment for performing thin-film deposition, such as CVD or ALD, is used to manufacture semiconductor devices. Such thin-film deposition equipment usually includes a showerhead provided inside a chamber to supply a reaction process fluid required for depositing a thin film on a wafer. The showerhead serves to spray the reaction process fluid onto the wafer in the proper distribution range required for thin film deposition.

One example of the showerhead is disclosed in Korean Patent No. 10-0769522 (hereinafter, referred to as “Patent Document 1”).

In Patent document 1, a showerhead is configured to spray a reaction gas introduced into a main hole and an auxiliary hole onto the wafer surface through a guide groove.

On the other hand, inside a vacuum chamber used for display manufacturing, a diffuser may be provided to uniformly spray gas onto glass. A display is a non-light emitting device in which liquid crystals are injected between an array substrate and a color filter substrate to obtain an image effect by using the characteristics thereof. The array substrate and the color filter substrate may be manufactured in such a manner that a thin film is repeatedly deposited onto a transparent substrate made of glass or the like, and patterning and etching are followed. In this case, when a reaction material and a source material in a gaseous phase are introduced into the vacuum chamber in a deposition process, introduced gases are passed through the diffuser and deposited onto glass installed on a susceptor to form a film.

One example of the diffuser is disclosed in Korean Patent No. 10-1352923 (hereinafter, referred to as “Patent Document 2”).

In Patent Document 2, a diffuser is disposed in an upper region in the chamber to provide a deposition material onto the surface of a glass substrate.

Fluid permeable members such as the showerhead of Patent Document 1 and the diffuser of Patent Document 2 may be influenced by the temperature inside an enclosed process chamber. When a fluid permeable member is under influence by temperature, a temperature deviation may occur in the fluid permeable member itself, which may cause deformation to occur. This may cause a problem in that the direction and density of process fluid distribution may not be uniform. In other words, when the fluid permeable member is influenced by the temperature inside the process chamber, there may arise a problem in that deformation of a product may occur, which may adversely influence functions of the product.

In order to compensate for the adverse influence of temperature on the fluid permeable member, it may be considered to provide a fluid permeable member, which includes a space therein capable of controlling the temperature of the fluid permeable member. As a method of manufacturing a fluid permeable member having a space capable of controlling temperature therein, a method of welding or brazing a metal filler material in a molten state may be used. FIGS. 1A and 1B are views showing a technology underlying the present invention, in which a fluid permeable member manufactured by welding or brazing a metal filler material in a molten state is partially enlarged. FIG. 1A is a view showing parent members 1 in a state before the method of welding or brazing the metal filler material in a molten state is used. FIG. 1B is a view showing a portion of a fluid permeable member manufactured by the method of welding or brazing the metal filler material in the molten state.

As shown in FIG. 1A, grooves 2 may be formed in opposed contact surfaces of the respective parent members 1 in an opposed relationship to define temperature control spaces 2. The parent members 1 in which the grooves 2 are formed may welded or brazed by using the molten metal filler material. After welding or brazing, holes 4 may be formed by use of a perforation method in regions in which no temperature control space is formed.

However, due to the fact the above technology uses a method of welding or brazing a metal filler material (e.g., filler metal in the case of welding) in a molten state, there may arise a problem that when the process fluid is injected through the holes 4, the metal filler material of a weld joint or braze joint 3 formed between the parent members 1, may be exposed to the process fluid, thus leading to increased corrosion. In detail, the above technology is characterized in that the weld joint or braze joint 3 is also present on inner surfaces of the holes 4. Due to this, there may arise a problem in that the weld joint or braze joint 3 may be exposed due to the process fluid injected through the inner surfaces of the holes 4, causing corrosion.

Such problems may be transferred to temperature control spaces such as the grooves 2 through the weld joint or braze joint 3, which is an interface between the parent members 1, to adversely influence the temperature control spaces. This may result in occurrence of serious functional errors of the temperature control spaces. When a functional error of the temperature control spaces occurs, there may arise a problem in that temperature distribution of a fluid permeable member may become uneven, which may cause positional deformation of the holes 4 and further cause deformation of a product itself. This may cause a problem of a functional error of the fluid permeable member to occur.

As such, according to the technology underlying the present invention, a conventional fusion bonding method has disadvantages that may cause various problems.

The foregoing is intended merely to aid in the understanding of the background of the present invention, and is not intended to mean that the present invention falls within the purview of the related art that is already known to those skilled in the art.

### DOCUMENTS OF RELATED ART

(Patent document 1) Korean Patent No. 10-0769522

(Patent document 2) Korean Patent No. 10-1352923

### SUMMARY OF THE INVENTION

Accordingly, the present invention has been made keeping in mind the above problems occurring in the related art, and an objective of the present invention is to provide a joined component that is manufactured by friction stir welding in a structure capable of temperature control, thus securing temperature uniformity and minimizing deformation of a product.

In order to achieve the above objective, according to one aspect of the present invention, there is provided a joined component through which a process fluid passes in a semiconductor manufacturing process or a display manufacturing process, the joined component being formed by joining at least two parent members by friction stir welding, and including: a hollow channel formed inside the joined component and including a temperature control means; and a hole vertically passing through the parent members and providing passages through which the process fluid passes, a weld zone by friction stir welding is formed to remove at least a part of a horizontal interface between each of the hollow channels and each of the holes.

According to another aspect of the present invention, there is provided a joined component through which a process fluid passes in a semiconductor manufacturing process or a display manufacturing process, the joined component being formed by joining at least two parent members by friction stir welding, and including: a hollow channel formed inside the joined component and including a temperature control means; and a hole vertically passing through an overlap portion where weld zones by friction stir welding at least partially overlap each other, wherein each of the weld zones by friction stir welding is formed to remove at least a part of a horizontal interface between the hollow channel and the hole.

Furthermore, the weld zone by friction stir welding may be formed along the hollow channel.

Furthermore, the temperature control means may be a fluid.

Furthermore, the temperature control means may be a heat wire.

Furthermore, the hole may be provided as multiple holes that are arranged in a spaced apart relationship at an interval of equal to or greater than 3 mm to equal to or less than 15 mm.

Furthermore, the joined component may be provided in etching equipment, cleaning equipment, heat treatment equipment, ion implantation equipment, sputtering equipment, or CVD equipment.

According to still another aspect of the present invention, there is provided a joined component through which a process fluid passes in a semiconductor manufacturing process or a display manufacturing process, the joined component being formed by joining at least two parent members by friction stir welding, and including: multiple holes vertically passing through the parent members and providing passages through which the process fluid passes; and a hollow channel provided between each of the holes and including a temperature control means, wherein the holes are arranged in a spaced apart relationship at an interval of equal to or greater than 3 mm to equal to or less than 15 mm, and a weld zone by friction stir welding is formed to remove at least a part of a horizontal interface between the hollow channel and each of the holes.

According to still another aspect of the present invention, there is provided a joined component through which a process fluid passes in a semiconductor manufacturing process or a display manufacturing process, the joined component being formed by joining at least two parent members by friction stir welding, and including: multiple hollow channels formed inside the joined component and each which includes a temperature control means; and at least two holes formed between each of the hollow channels by vertically passing through the parent members, and providing passages through which the process fluid passes, wherein the holes are arranged in a spaced apart relationship at an interval of equal to or greater than 3 mm to equal to or less than 15 mm, and a weld zone by friction stir welding is formed to remove at least a part of a horizontal interface between each of the hollow channels and each of the holes.

As described above, the joined component according to the present invention provides an advantage of preventing adverse interaction between the hollow channels and the holes to effectively secure uniformity of the temperature of a product itself, thus providing a product in which deformation is minimized and no functional error occurs.

### BRIEF DESCRIPTION OF THE DRAWINGS

The above and other objectives, features, and other advantages of the present invention will be more clearly understood from the following detailed description when taken in conjunction with the accompanying drawings, in which:

FIGS. 1A to 1B are views schematically showing a technology underlying the present invention;

FIGS. 2A and 2B are views schematically showing a first embodiment of the present invention, welded by friction stir welding which is a technical feature of the present invention;

FIGS. 3A and 3B are views showing a joined component according to the first embodiment of the present invention;

FIGS. 4A to 4D-2 are views schematically showing a manufacturing process of FIG. 3;

FIGS. 5A to 5D-2 are views schematically showing a manufacturing process of a second embodiment;

FIGS. 6A to 6D-2 are views schematically showing a manufacturing process of a first modification of the second embodiment of the present invention;

FIGS. 7A to 7D-2 are views schematically showing a manufacturing process of a second modification of the second embodiment of the present invention;

FIGS. 8A and 8B are views showing a direction of flow of cooling or heating fluid when a hollow channel has a one-layer structure;

FIGS. 9A to 9E are views schematically showing a manufacturing process of a third embodiment of the present invention;

FIG. 10 is a view showing a modification of the third embodiment of the present invention;

FIGS. 11A to 11C are views showing a direction of flow of cooling or heating fluid when a hollow channel has a multi-layer structure;

FIG. 12 is a view schematically showing semiconductor manufacturing process equipment; and

FIG. 13 is a view schematically showing display manufacturing process equipment.

### DETAILED DESCRIPTION OF THE INVENTION

The following description merely exemplifies the principle of the present invention. Thus, although not explicitly described or shown in this disclosure, various devices in which the principle of the present invention is implemented and which are encompassed in the concept or scope of the present invention can be invented by one of ordinary skill in the art. It should be appreciated that all the conditional terms enumerated herein and embodiments are clearly intended only for a better understanding of the concept of the present invention, and the present invention is not limited to the particularly described embodiments and statuses.

The forgoing objectives, advantages, and features of invention will become more readily apparent from the following detailed description taken in conjunction with the accompanying drawings, and accordingly, one of ordinary skill in the art may easily practice the embodiment of the present invention.

Embodiments are described herein with reference to sectional and/or perspective illustrations that are schematic illustrations of idealized embodiments. Also, for convenience of understanding of the elements, in the figures, thicknesses of members and regions and diameters of holes may be exaggerated to be large for clarity of illustration. As such, variations from the shapes of the illustrations as a result, for example, of manufacturing techniques and/or tolerances, are to be expected. In addition, the number of holes shown in the drawings is by way of example only. Thus, embodiments should not be construed as limited to the particular shapes illustrated herein but are to include deviations in shapes that result, for example, from manufacturing.

Wherever possible, the same reference numerals will be used throughout different embodiments and the description to refer to the same or like elements or parts having like functions throughout. Furthermore, the configuration and operation already described in other embodiments will be omitted for convenience of the description.

Hereinbelow, exemplary embodiments of the present invention will be described in detail with reference to the accompanying drawings.

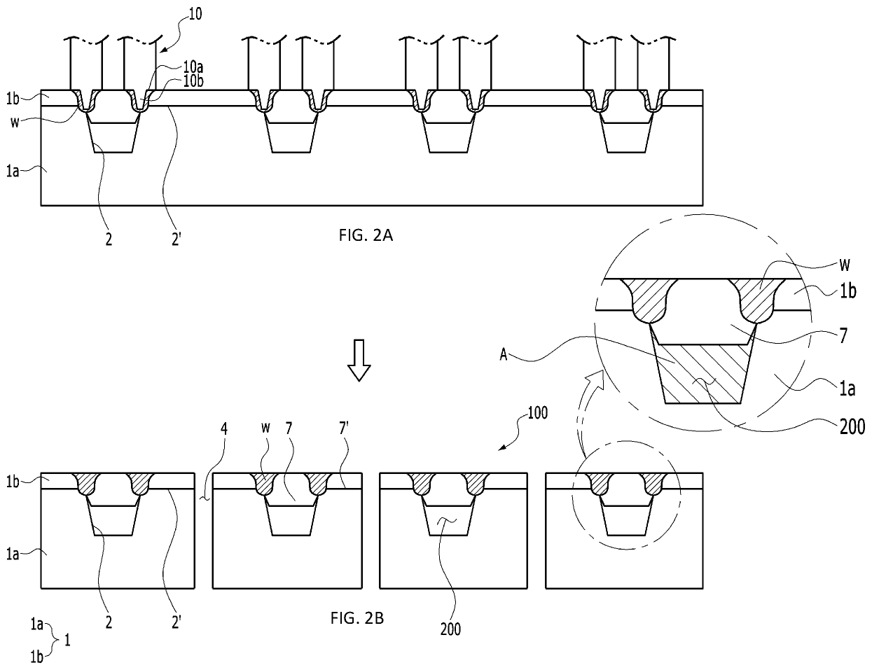

FIGS. 2A and 2B are views schematically showing an enlarged part of a weld zone of a joined component 100 according to a first embodiment of the present invention, welded by friction stir welding which is a technical feature of the present invention. As shown in FIG. 2A, at least two parent members 1 may be joined by friction stir welding. FIGS. 2A and 2B show, as an example, that at least two parent members 1 are stacked on top of each other and joined by friction stir welding, but are not limited thereto.

As shown in FIGS. 2A and 2B, the joined component 100 may include at least two parent members 1, a hollow channel 200 formed inside the joined component 100 and including a temperature control means, and a hole 4 vertically passing through the parent members land through which a process fluid passes. When the parent members 1 are stacked on top of each other and welded, the parent members 1 may be comprised of a first parent member 1a located at a lower position on the drawings, and a second parent member 1b located on top of the first parent member 1a.

As shown in FIG. 2A, the first parent member 1a and the second parent member 1b may be joined by friction stir welding. Friction stir welding may be performed along a contact junction formed on at least a part of each interface between the parent members 1 to form a weld zone w, while at least a part, other than the contact junction where the weld zone w is formed, may remain unwelded.

On the other hand, as in the embodiment of the present invention, when friction stir welding is performed along at least a part of each of the interfaces between at least two parent members 1 and at least a part remains unwelded, the parent members 1 exhibit a separate behavior in a region except for the weld zone W. In the configuration in which the parent members 1 are partially welded, the cross-sectional area is divided into upper and lower two areas and has a separate behavior in response to application of a bending force. On the contrary, in the configuration in which the parent members 1 are entirely welded, the cross-sectional area exhibits an integrated behavior in response to application of a bending force. Therefore, in the configuration in which at least two parent members 1 are partially welded as in the embodiment of the present invention, it is ensured that correction of bending deformation by the temperature control means is made more quickly, which is advantageous over the configuration in which at least two parent members 1 are entirely welded.

Friction stir welding is a process that joins workpieces without melting the workpiece material. Friction stir welding can reduce generation of defects such as pores, solidification cracks, and residual stresses due to a phase change from liquid to solid, which is advantageous over conventional welding or brazing. When friction stir welding is performed along the contact junction formed at each interface between the parent members 1, a pin 10b is brought into friction contact with the parent members and generates heat. In this state, a shoulder 10a coupled to an upper portion of the pin 10b is brought into contact with the parent members and expands the heating area. Then, the pin 10b or the parent members 1 are moved to cause the material under the pin to plastically flow to form a friction stir welding nugget zone. The nugget zone is a region where recovery and recrystallization occurs due to high heat and the amount of deformation, also called a dynamic recrystallization zone.

Unlike general welding in which melting occurs due to heat, the nugget zone is formed through dynamic recrystallization of the material which occurs in a solid state below the melting point due to frictional heat and stirring. The diameter of the nugget zone is larger than that of the pin 10b while being smaller than that of the shoulder 10a. The size of the nugget zone depends on the speed of rotation of a welding tool 10 including the pin 10b and the shoulder 10a. As the speed of rotation increases, the size of the nugget zone decreases. However, when the speed of rotation is too high, the shape of crystal grains may be incomplete, and defects may occur at the incomplete portion. In the vicinity of the nugget zone where the parent members 1 are mixed during friction stir welding, a thermo-mechanically affected zone (TMAZ) surrounding the nugget zone is formed, and a heat affected zone (HAZ) surrounding the thermo-mechanically affected zone is formed.

The thermo-mechanically affected zone is a region where partial recrystallization occurs due to plastic deformation caused by friction at a contact surface where the shoulder 10a of the welding tool 10 is brought into contact with the parent members, and where thermal deformation due to friction and mechanical deformation due to the shoulder 10a simultaneously occur. In the thermo-mechanically affected zone, crystals softened due to excessive plastic flow and deformation of the material may be distributed at an angle.

The heat affected zone is a region more affected by heat than the thermo-mechanically affected zone, in which slant crystal grains are present and many pores are present.

The weld zone w formed by friction stir welding may be a region including the nugget zone, the thermo-mechanically affected zone, and the heat affected zone. Preferably, the weld zone w may be a region where the nugget zone and the thermo-mechanically affected zone are formed below each interface between the parent members 1, or a region where the nugget zone is formed below each interface between the parent members 1.

The material of the parent members 1 may be any material enables that: i) frictional heat is generated by friction between the pin 10b rotating at a high speed and the parent members 1, ii) the parent members 1 around the pin 10b are softened by the frictional heat, and iii) the parent members 1 are forcibly mixed together by plastic flow of the parent members 1 occurring on the joined surfaces by a stirring action of the pin 10b. The material of the parent members 1 constituting a joined component 100 may be made of at least one of aluminum, aluminum alloy, titanium, titanium alloy, magnesium, magnesium alloy, carbon steel, and stainless steel. The material of the parent members 1 may be composed of at least one of non-ferrous metal including aluminum, aluminum alloys, titanium, titanium alloys, magnesium, magnesium alloys, and the like, and carbon steel, and stainless steel, but is not limited thereto.

When at least two parent members 1 are joined by friction stir welding, the at least two parent members 1 may be made of dissimilar metal materials. For example, when the first parent member 1a is made of aluminum, which is one of the above materials, the second parent member 1b may be made of stainless steel. On the other hand, the parent members 1 may be made of the same metal material. For example, when the first parent member 1a is made of aluminum, the second parent member 1b may also be made of aluminum, and when the first parent member 1a is stainless steel, the second parent member 1b may also be made of stainless steel. Friction stir welding is a solid-state joining process, and thus members having different melting points can be stably joined. In other words, it is possible to stably join dissimilar metal materials. In particular, the nugget zone included in the weld zone w is a region in which dynamic recrystallization occurs, and thus the nugget zone has a structure resistant to external vibrations and impacts. Furthermore, the thermo-mechanically affected zone included in the weld zone w is a region in which the parent members 1 are mixed and joined, and thus thermo-mechanically affected zone has a structure resistant to external vibrations and impacts. Unlike other welding processes such as a welding process of joining a metal filler material in a molten state, a brazing process, and the like, friction stir welding does not require a heat source, a welding rod, a filler metal, and the like, and thus no harmful rays or harmful substances are emitted during welding. Furthermore, dynamic recombination occurs, and thus it is possible to prevent solidification cracks which may occur in conventional welding, and there is little deformation and thus mechanical properties are excellent.

According to the present invention, it is ensured that a weld zone w having such a high strength and weldability is formed inside the joined component 100. By removing at a least a part of a horizontal interface between the hollow channel 200 including the temperature control means and the hole 4 through which the process fluid passes, it is also ensured that particles generated inside the hole 4 are prevented from moving to the hollow channel 200. It is further ensured that the process fluid passing through the hole 4 is prevented from penetrating along the horizontal interface to reach the hollow channel 200, and the temperature control means such as a temperature control fluid passing through the hollow channel 200 is prevented from penetrating along the horizontal interface to reach the hole 4.

A groove 2 may be formed in at least one of opposed contact surfaces of the parent members 1. Due to this configuration, when the first parent member 1a and the second parent member 1b are joined by friction stir welding to form the joined component 100, the hollow channel 200 is defined inside the joined component 100 by the groove 2. When the groove 2 is formed in at least one of the contact surfaces of the parent members 1, there may be provided a groove region in which the groove 2 is formed and a non-groove region 2′ in which the groove 2 is not formed. For example, when the groove 2 is formed in the contact surface of the first parent member 1a, the first parent member 1a may include the groove region and the non-groove region 2′. In this case, the groove region of the first parent member 1a and a first region of the second parent member 1b, which are in an opposed relationship, may not be welded, while the non-groove region 2′ of the first parent member 1a and a second region of the second parent member 1b, which are in an opposed relationship, may be welded by friction stir welding to form a weld zone w. In this case, friction stir welding may be performed along a contact junction formed on at least a part of an interface between the non-groove region 2′ of the first parent member 1a and the second region of the second parent member 1b, and a weld zone W is formed thereby.

Meanwhile, a hole 4 may be formed at a position where the weld zone w is not formed in the non-groove region 2′ of the first parent member 1a and the second region of the second parent member 1b, which are in an opposed relationship, by vertically passing through the parent members 1. The hole 4 provides a passage through which the process fluid passes. It is preferable that the hole 4 is formed at a position where the weld zone w is not formed in the non-groove region 2′ of the first parent member 1a and the second region of the second parent member 1b, which are in an opposed relationship, and the weld zone W is formed between the hollow channel 200 and the hole 4. In this case, the weld zone w formed by friction stir welding removes at a least a part of the horizontal interface between the hollow channel 200 and the hole 4. Due to this, it is possible to prevent occurrence of any adverse interaction between the hollow channel 200 and the hole 4, such as leakage or corrosion which may cause particle leakage.

As shown in FIGS. 2A and 2B, the parent members 1 may have shapes capable of fitting together and may first fitted together before being joined by friction stir welding. The parent members 1 having shapes capable of fitting together may be configured such that a recessed portion such as a groove 2 is formed in the contact surface of at least one of the parent members 1, and a protrusion 7 may be formed on the contact surface of a remaining one of the parent members 1. In the present invention, the groove 2 is formed in the contact surface of the first parent member 1a and the protrusion 7 is formed on the contact surface of the second parent member 1b such that the first and second parent members 1a and 1b are fitted together through engagement of the groove and the protrusion. However, this is only an example, and the shape of the parent members 1 is not limited thereto. In other words, the parent members 1 may be provided in a shape other than the shapes capable of fitting together. In addition, in the present invention, the groove 2 and the protrusion 7 have a tapered shape. However, this is only an example, and the shape of the groove 2 and the protrusion 7 is not limited thereto. Hereinafter, the parent members 1 will be described as having shapes capable of fitting together to form the joined component 100.

In the contact surface of the first parent member 1a, the groove region in which the groove 2 is formed, and the non-groove non-region 2′ in which the groove 2 is not formed may be provided. Meanwhile, in the contact surface of the second parent member 1b, a protrusion region in which the protrusion 7 is formed, and a non-protrusion region 7′ in which the protrusion 7 is not formed may be provided. In this case, the groove region of the first parent member 1a and the protrusion region of the second parent member 1b may be opposed to each other, while the non-groove region of the first parent member 1a and the non-protrusion region of the second parent member 1b may opposed to each other.

The groove 2 formed in the contact surface of the first parent member 1a may be larger in depth than the protrusion 7 such that a lower surface of the protrusion 7 and a lower surface of the groove 2 are not brought into contact with each other when the protrusion 7 of the second parent member 1b is fitted into the groove 2. Due to this configuration, when the second parent member 1b is fitted to the first parent member 1a, a temperature control space is defined between the groove 2 of the first parent member 1a and the protrusion 7 of the second parent member 1b. The temperature control space defines the hollow channel 200 inside the joined component 100 when the first and second parent members 1a and 1b are welded by friction stir welding to form the joined component 100.

When the parent members 1 are fitted together, a contact junction may be formed. Friction stir welding may be performed along the contact junction to form a weld zone w. As shown in FIG. 2A, the second parent member 1b may be fitted to the first parent member 1a. In this case, the protrusion 7 of the second parent member 1b may be fitted into the groove 2 of the first parent member 1a. The fitting may be performed in such a manner that left and right contact surfaces of the protrusion 7 of the second parent member 1b in a width direction are brought into contact with left and right contact surfaces of the groove of the first parent member 1a in a width direction, respectively, with the lower surface of the protrusion 7 of the second parent member 1b not coming into contact with the lower surface of the groove 2 of the first parent member 1a. As a result, a contact junction is formed on at least a part of an interface between the groove 2 and the protrusion 7. Hereinafter, the parent members 1 will be described as an example that have shapes capable of fitting together and are welded by friction stir welding. Therefore, a contact junction described below may mean an interface between the groove 2 and the protrusion 7. In addition, due to the fact that friction stir welding is performed along the contact junction to form a weld zone w, at a least a part of each horizontal interface between the parent members 1 may be included in the weld zone w.

As described above, when the second parent member 1b is fitted to the first parent member 1a, and the left and right contact surfaces of the protrusion 7 of the second parent member 1b in the width direction are brought into contact with the left and right contact surfaces of the groove 2 of the first parent member 1a in the width direction, respectively, and the contact junctions are formed. Friction stir welding may be performed along the contact junctions to form weld zones w. In detail, when the left contact surface (on the drawings) of the groove 2 of the first parent member 1a in the width direction and the left outer side (on the drawings) of the protrusion 7 of the second parent member 1b in the width direction are brought into contact with each other, a left contact junction may be formed on at least a part of an interface between the groove 2 and the protrusion 7. Friction stir welding may be performed along the left contact junction to form a weld zone W. Furthermore, when the right contact surface of the groove 2 of the first parent member 1a in the width direction and the right contact surface of the protrusion 7 of the second parent member 1b in the width direction are brought into contact with each other, a right contact junction may be formed on at least a part of a right interface between the groove 2 and the protrusion 7. Friction stir welding may be performed along the left contact junction to form a weld zone W. Due to the fact that friction stir welding is performed along the left and right contact junctions between the groove and the protrusion of the parent members 1 to form the respective weld zones w, the joined component 100 may have a shape including multiple weld zones 100 formed on at least a part thereof.

In the joined component 100 according to the first embodiment, although described as an example that the weld zones w are formed on the respective left and right contact junctions, the weld zones w may be formed as one weld zone w having a range within which the left contact junction and the right contact junctions are included. Herein, the one weld zone W may be larger in width than the groove 2 of the first parent member 1a and than the protrusion 7 of the second parent member 1b and may be located a position below the horizontal interface between the hollow channel 200 and the hole 4, with a depth not exceeding the height of the protrusion 7 of the second parent member 1b.

Due to the formation of the weld zones W on the contact junctions between the parent members 1, the temperature control space defined by the groove 2 of the first parent member 1a and the protrusion 7 of the second parent member 1b, that is, the hollow channel 200 of the joined component 100, may have a shape that passes through an interior of the joined component 100. Such a shape of the hollow channel 200 may be formed by each of the weld zones w that removes a part of each interface between the parent members 1, the part being adjacent to the hollow channel 200. As a result, it is possible that particles that may be introduced into the hollow channel 200 along the interfaces between the parent members 1 are blocked, and other adverse influences are prevented.

As shown in FIG. 2B, the hole 4 providing a passage through which the process fluid passes may be formed in at least a part of the non-groove region of the first parent member 1a and the non-protrusion region of the second parent member 1b, which are in an opposed relationship, by vertically passing through the parent members 1. In detail, multiple grooves 2 may be arranged in the contact surface of the first parent member 1a in a spaced apart relationship, such that groove regions and non-groove regions 2′ may be arranged in alternate relationship. Furthermore, multiple protrusions 7 may be formed in the contact surface of the second parent member 1b in a spaced apart relationship, such that protrusion regions and non-protrusion regions 7′ may be alternately arranged. In this case, the groove regions of the first parent member 1a and the protrusion regions of the second parent member 1b may be opposed to each other, while the non-groove regions of the first parent member 1a and the non-protrusion regions of the second parent member 1b may be opposed to each other. When the first and second parent members 1a and 1b having the above configurations are first fitted together, the contact junctions are formed. Friction stir welding is performed along the contact junctions to form the multiple weld zones w.

As shown in FIG. 2B, each of the weld zones W friction stir welding is formed on each of the contact junction formed on at least a part of each interface between the parent members 1. This results in formation of non-weld areas. The non-weld areas are formed between left and right contact surfaces (on the drawings) of each of the grooves 2 of the first parent member 1a and left and right contact surfaces (on the drawings) of each of the protrusions 7 of the second parent member 7, respectively. Due to the non-weld areas, when a temperature control means such as cooling or heating fluid (liquid or gas) provided in the hollow channel 200 moves inside the joined component 100, it is ensured that the contact area A between the temperature control means and the joined component 100 increases. The non-weld areas provide an increased area where the temperature control means can move, and thus it is ensured that temperature control effect of the joined component 100 is further improved. Furthermore, the non-weld areas are formed at positions below the weld zones W, and thus it is possible to prevent the problem of introduction of particles by friction stir welding by the weld zones w.

Due to the fact that the hole 4 is formed by vertically passing through at least a part of the non-groove region of the first parent member 1a and at least a part of the non-protrusion region of the second parent member 1b, which are in an opposed relationship, the hole 4 may have a shape formed between adjacent weld zones w located with the opposed non-groove and non-protrusion regions interposed therebetween.

The hole 4 formed by passing through the parent members 1 at a position between the adjacent weld zones w may be provided as an array of multiple holes 4 that are arranged at an interval of equal to or greater than 3 mm to equal to or less than 15 mm. In other words, the array of multiple holes 4 may be formed between the adjacent weld zones w, and the multiple holes 4 may be arranged in a spaced apart relationship at an interval of equal to or greater than 3 mm to equal to or less than 15 mm. The holes 4 are formed to appropriately maintain the arrangement interval at an interval of equal to or greater than 3 mm to equal to or less than 15 mm, and thus it is ensured that a temperature control function of the hollow channel 200, which is the temperature control space, is effectively achieved.

On the other hand, multiple holes 4 vertically passing through the parent members 1 may be provided in the joined component 100, and the hollow channel 200 may be provided between each of the holes 4. In this case, the holes 4 may be arranged in a spaced apart relationship at an interval of equal to or greater than 3 mm to equal to or less than 15 mm. In the above joined component 100, each of the weld zones w by friction stir welding is formed to remove at a least a part of the horizontal interface between each of the hollow channels 200 and the each of the holes 4. As a result, it is ensured that adverse interaction between the hollow channels 200 and the holes 4 is prevented, and that the function of the temperature control means provided in the hollow channels 200 is effectively performed. In addition, due to the interval of equal to or greater than 3 mm to equal to or less than 15 mm between the holes 4, it is ensured that a temperature control function of the hollow channels 200 is effectively performed. In detail, when the interval between the holes 4 is too large, there may be a problem in that the temperature control function of the temperature control means provided in the hollow channels 200 may be degraded. When the interval between the holes 4 is too small, it may be difficult to provide the temperature control means in the hollow channels 200. This is why it is preferable that the interval between the holes 4 is equal to or greater than 3 mm to equal to or less than 15 mm.

The holes 4 do not cause adverse interaction with the hollow channels 200 because of the weld zones w. In detail, the weld zones w are formed on the contact junctions between the parent members 1. Accordingly, each of the weld zones W removes at a least a part of the horizontal interface between each of the hollow channels 200 and the each of the holes 4. As a result, it is ensured that even when an interface between the parent members 1 where the holes 4 are formed remains unwelded, the process fluid passing through the holes 4 is prevented from adversely influencing the hollow channels 200 along the interface.

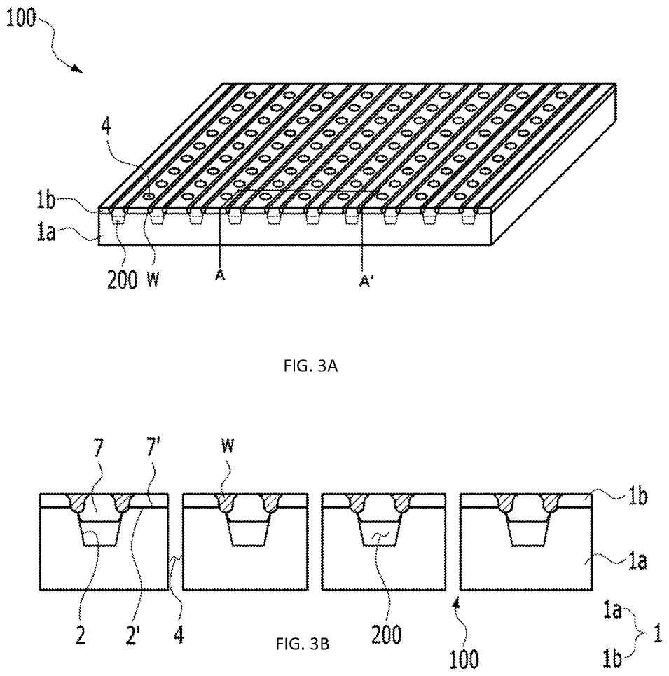

FIG. 3A is a perspective view showing the joined component 100 according to the first embodiment of the present invention, and FIG. 3B is a sectional view taken along line A-A′ of FIG. 3A. As shown in FIGS. 3A and 3B, the joined component 100 includes the first and second parent members 1a and 1b, the hollow channels 200, and the holes 4. Hereinafter, the joined component 100 will be described as having a quadrangular section. However, the sectional shape of the joined component 100 is not limited thereto and may have a suitable sectional shape according to the configuration.

As shown in FIG. 3A, the weld zones w by friction stir welding may be formed along the hollow channels 200, whereby each of the weld zones w removes at a least a part of the horizontal interface between each of the hollow channels 200 and the each of holes 4.

Each of the hollow channels 200 may include the temperature control means (not shown).

The temperature control means may be provided in each of the grooves 2 formed in at least one of the contact surfaces of the parent members 1 such that the temperature control means is provided in each of the hollow channels 200 formed inside the joined component 100. This imparts a temperature control function to the joined component 100 such that the joined component controls the temperature itself through the temperature control means. The provision of the temperature control mean ensures that the joined component 100 has an effect of securing temperature uniformity and of minimizing occurrence of a problem of malfunction due to product deformation.

The temperature control means may be a fluid. In this case, the fluid may be any fluid including a cooling fluid (liquid or gas) or a heating fluid (liquid or gas). When the temperature control means is a fluid, the joined component 100 may function as a cooling block or a heating block depending on the fluid. On the other hand, the temperature control means may be a heating wire. Due to the provision of the fluid or the heating wire as the temperature control means, the joined component 100 has a cooling and/or heating function.

The holes 4 may be formed by vertically passing through the parent members 1 while being surrounded by the adjacent weld zones w formed by friction stir welding. In this case, the array of multiple holes 4 may be provided between the adjacent weld zones w. The multiple holes 4 may be arranged in a spaced apart relationship at an interval of equal to or greater than 3 mm to equal to or less than 15 mm.

Each of the weld zones w of the joined component 100 removes at a least a part of the horizontal interface between each of the hollow channels 200 and each of the holes 4. As a result, it is possible to prevent mutual physical and chemical actions between the hollow channels 200 and the holes 4.

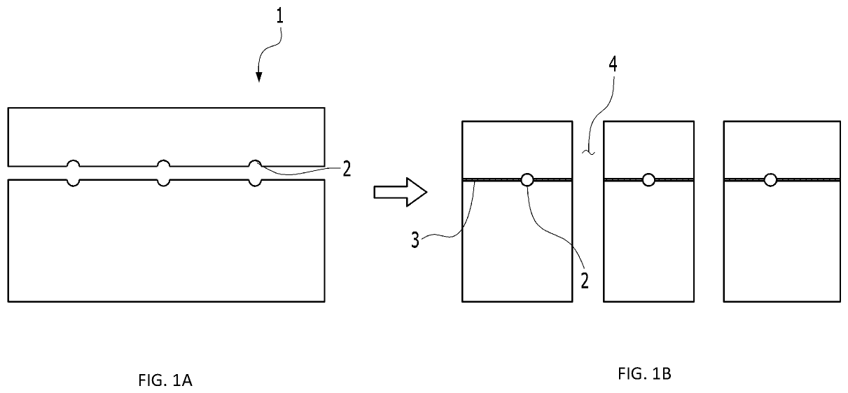

When the parent members 1 are joined by welding or brazing as shown in FIGS. 1A and 1B, a weld joint or braze joint 3 is formed between the first and second parent members 1a 1b as shown in FIG. 1B. Such a weld joint or braze joint 3 may be exposed to the process fluid injected into the holes 4. This may cause problems of corrosion of the inner surfaces of the holes 4 and particle generation, and the particles may move to the hollow channels 200 along the weld joint or braze joint 3 and adversely influence the function of the hollow channels 200.

However, in the joined component 100 according to the present invention, due to the fact that each of the weld zones w formed by friction stir welding the parent members 1 removes a part of the horizontal interface between each of the hollow channels 200 and each of the holes 4, hollow channels 200 and the holes 4 may be blocked from each other by the weld zones. Therefore, the process fluid which may cause corrosion or leakage in the holes 4 is blocked by the weld zones w before entering the hollow channels 200 along the interface, resulting that the mutual physical and chemical action between the hollow channels 200 and the holes 4 is prevented.

In other words, in the joined component 100 according to the present invention, each of the weld zones w removes a part of the horizontal interface between each of the hollow channels 200 and each of the holes 4, whereby a boundaryless region that result from partial removal of the interface is formed between the hollow channel 200 and the hole 4. As a result, it is possible to prevent adverse interaction between the hollow channels 200 and the holes 4 from occurring.

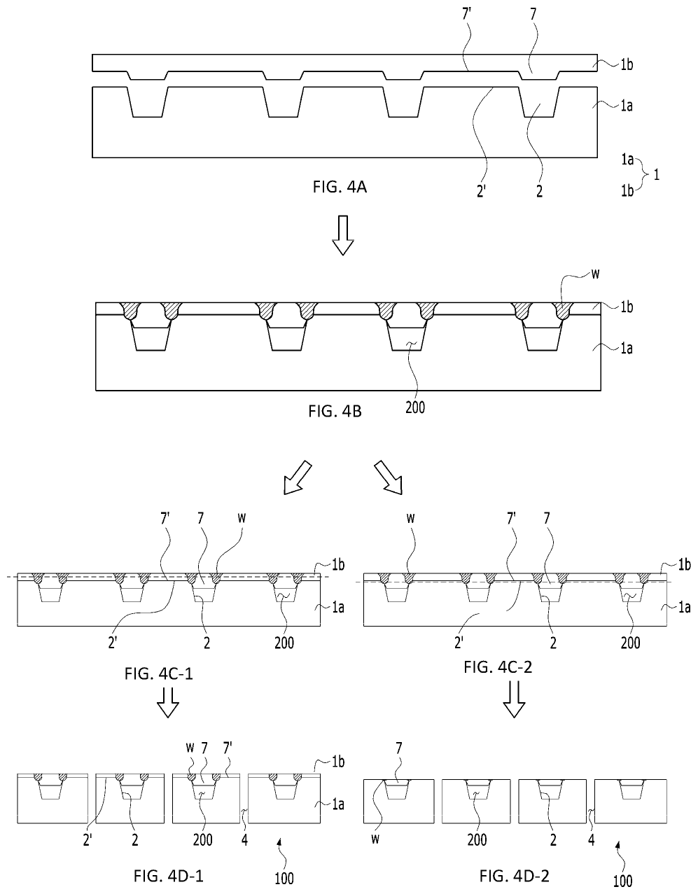

FIGS. 4A to 4D-2 are views schematically showing a manufacturing process of the joined component 100 according to the first embodiment of the present invention.

First, as shown in FIG. 4A, the first parent member 1a is placed at a lower position on the drawings, and the second parent member 1b is placed on top of the first parent member 1a. The first parent member 1a includes groove regions and non-groove regions, and the second parent member 1b includes protrusion regions and non-protrusion regions. In this case, the groove regions of the first parent member 1a and the protrusion regions of the second parent member 1b are located in an opposed relationship, while the non-groove regions of the first parent member 1a and the non-protrusion regions of the second parent member 1b are located in an opposed relationship.

Then, as shown in FIG. 4B, the second parent member 1b is fitted to the first parent member 1a, and then friction stir welding is performed along the contact junctions between the parent members fitted together to form the weld zones. In this case, the groove regions of the first parent member 1a may be larger in depth than the protrusion regions of the second parent member 1b such that the hollow channels 200 are defined inside a manufactured joined component 100.

Then, a process of planarizing the weld zones w by friction stir welding may be performed. At least a part of each of the weld zones w may be planarized.

As shown in FIG. 4C-1, planarizing may be performed at a position above horizontal interfaces between the parent members 1, the position being indicated by a dotted line. Then, the holes 4 vertically passing through the patent members 1 may be formed to obtain a joined component 100 having a shape as shown in FIG. 4D-1.

Alternatively, as shown in FIG. 4C-2, planarizing may be performed at a position below the horizontal interfaces between the parent members 1, the position being indicated by a dotted line, within a range that does not deviate from the positions of the weld zones w, with respect to a downward direction on the drawings. Then, the holes 4 vertically passing through the parent members 1 may be formed to obtain a joined component 100 having a shape as shown in FIG. 4D-2.

In FIG. 4D-1, the horizontal interfaces exist between the holes 4 and the hollow channels 200.

On the contrary, in the structure of FIG. 4D-2, unlike FIG. 4D-1, no horizontal interface exists between the holes 4 and the hollow channels 200. As a result, it is possible to prevent the problem of particle generation that may occur at the horizontal interfaces.

Hereinafter, a joined component 100 according to a second preferred embodiment of the present invention will be described.

The joined component 100 according to the second embodiment differs from the first embodiment in that the positions where holes 4 are formed are overlap portions 11 of weld zones w by friction stir welding. Other configurations are the same as those of the first embodiment, and thus the duplicate description thereof will not be repeated.

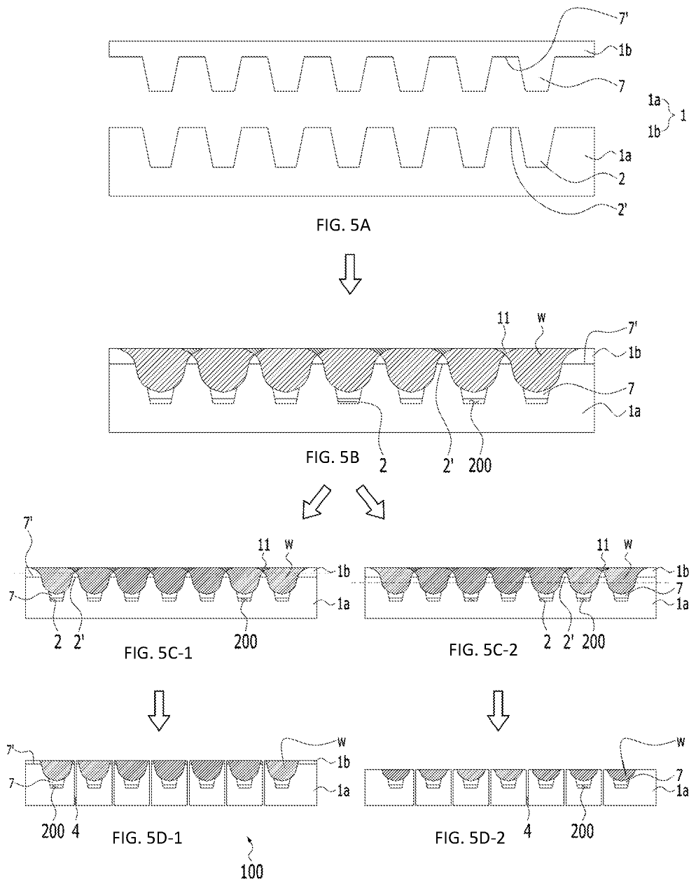

FIGS. 5A to 5D-2 are views schematically showing a manufacturing process of the second embodiment of the present invention.

The joined component 100 according to the second embodiment is constituted by at least two parent members 1 that are joined by friction stir welding. The joined component 100 includes: hollow channels 200 formed therein and each includes temperature control means provided therein; and holes 4 formed by vertically passing through overlap portions 11 where weld zones 4 at least partially overlap each other, and providing passages through which a process fluid passes. In this case, each of the weld zones w by friction stir welding removes at least a part of a horizontal interface between each of the hollow channels 200 and each of the holes 4.

First, as shown in FIG. 5A, a first parent member 1a located at a lower position on the drawings is placed, and a second parent member 1b is placed on top of the first parent member 1a. The first parent member 1a includes groove regions and non-groove regions, and the second parent member 1b includes protrusion regions and non-protrusion regions. In this case, the groove regions of the first parent member 1a and the protrusion regions of the second parent member 1b are located in an opposed relationship, while the non-groove regions of the first parent member 1a and the non-protrusion regions of the second parent member 1b are located in an opposed relationship.

Then, the second parent member 1b is fitted to the first parent member 1a, and contact junctions are formed thereby. Then, as shown in FIG. 5B, friction stir welding is performed along the contact junctions to form weld zones w. Each of the weld zones w is formed to remove at least a part of a horizontal interface between each of the hollow channels 200 and each of the holes 4. In this case, the weld zone w may be formed larger in width than each of grooves 2 of the first parent member 1a and each of protrusions 7 of the second parent member 1b. In addition, the weld zone w may be formed such that the depth thereof reaches a position below the horizontal interface between each of the hollow channels 200 and each of the holes 4, without exceeding the height of the protrusion 7 of the second parent member 1b. As a result, it is possible to prevent the problem that particles in the weld zones w are introduced through non-weld areas, causing a functional error of the hollow channels 200.

The weld zones W may be formed with the width and depth as above. The range of each of the weld zones W may include left and right contact junctions, the left contact junction being formed on at least a part of a left interface between a left contact surface (on the drawings) of each of the grooves 2 of the first parent member 1a and a left contact surface (on the drawings) of each of the protrusions 7 of the second parent member 1b, the right contact junction being formed on at least a part of a right interface between a right contact surface (on the drawings) of the groove 2 of the first parent member 1a and a right contact surface (on the drawings) of the protrusion 7 of the second parent member 1b. Due to this, each of the weld zones w removes at least a part of each of the left and right interfaces between each of the grooves 2 of the first parent member 1a and each of the protrusions 7 of the second parent member 1b. In addition, at least a part of the horizontal interface between each of the hollow channels 200 and each of the holes 4 is removed.

When each of the weld zones w is formed to entirely includes the left and right contact junctions and at least a part of the horizontal interface between each of the hollow channels 200 and each of the holes 4, at a least a part of a first weld zone located at the leftmost side on FIG. 5B and at a least a part of a second weld zone adjacent to the first weld zone overlap each other to form an overlap portion 11. Each of the weld zones w includes a nugget zone, a thermo-mechanically affected zone, and a heat affected zone. Therefore, the overlap portion 11 may be formed such that the zones constituting the weld zones w at least partially overlap each other. The overlap portion 11 may be a portion that may be formed when the interval between the hollow channels 200 formed inside the joined component 100 is relatively small. Alternatively, the overlap portion 11 may be a portion that may be defined by an insertion depth when the interval between the hollow channels is relatively large but a shoulder 10a and a pin 10b of a welding tool 10 performing friction stir welding are deeply inserted to form the weld zones w.

After friction stir welding is performed along the contact junctions of the parent members 1 to form the weld zones w, a process of planarizing the weld zones w may be performed. At least a part of each of the weld zones w may be planarized.

As shown in FIG. 5C-1, planarizing may be performed at a position above the horizontal interfaces between the parent members 1, the position being indicated by a dotted line. In other words, planarizing may be performed above the horizontal interfaces between the parent members 1.

Then, the holes 4 vertically passing through the overlap portions 11 may be formed to obtain a joined component 100 having a shape as shown in FIG. 5D-1.

Due to the fact that each of the weld zones w are formed to remove at least a part of the horizontal interface between each of the hollow channels 200 and each of the holes 4, it is ensured that adverse interaction which may occur between the holes 4 formed in overlap portions 11 and the hollow channels 200 is prevented by the weld zones W. In other words, movement of the fluid passing through the holes 4 to the hollow channels 200 along the interfaces between the parent members 1 is blocked by the weld zones w. As a result, it is ensured that the temperature control means provided in the hollow channels 200 is protected against adverse influence, thus effectively perform the function thereof. Furthermore, formation of the weld zones W results in a non-weld area. The non-weld area is formed in at least a part between the contact surfaces of each of the grooves 2 of the first parent member 1a and the contact surfaces of each of the protrusions 7 of the second parent member 1b. This ensures that the contact area A between the temperature control means and the first parent member 1a increases and thus the temperature control function is further improved. As a result, it is possible to provide a joined component 100 having a uniform temperature, with minimized deformation.

Alternatively, as shown in FIG. 5C-2, planarizing may be performed at a position below the horizontal interfaces between the parent members 1, the position being indicated by the a dotted line, within a range that does not deviate from the positions of the weld zones w, with respect to a downward direction on the drawings. In other words, planarizing may be performed below the horizontal interfaces between the parent members 1. A planarizing surface along which planarizing is performed may be located between the depth of the weld zones w and the horizontal interfaces. Then, the holes 4 vertically passing through the overlap portions 11 may be formed to obtain a joined component 100 having a shape as shown in FIG. 5D-2.

In FIG. 5D-1, horizontal interfaces exist between the holes 4 and the hollow channels 200.

On the contrary, in the structure of FIG. 5D-2, unlike FIG. 5D-1, no horizontal interface exists between the holes 4 and the hollow channels 200. As a result, it is possible to prevent the problem of particle generation that may occur at the horizontal interfaces.

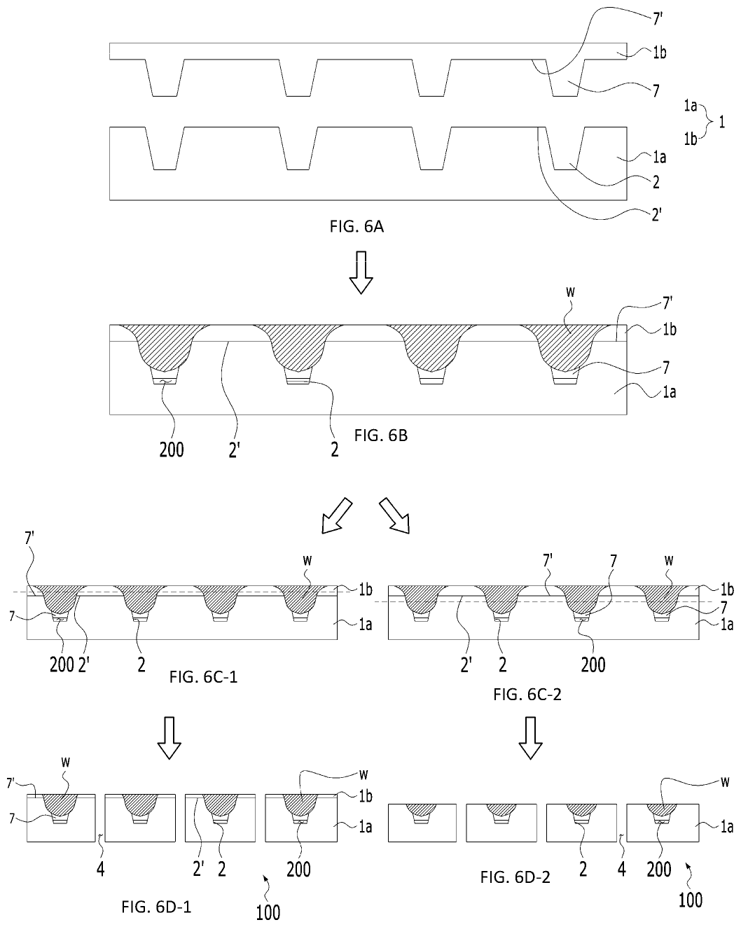

FIGS. 6A to 6D-2 are views schematically showing a manufacturing process of a first modification of the joined component 100 according to the second embodiment. A joined component 100 according to the first modification differs from the second embodiment in that the interval between multiple hollow channels 200 is relatively larger than that of the second embodiment and thus overlap portions 11 are not formed, but holes 4 are formed between the hollow channels 200.

First, as shown in FIG. 6A, a first parent member 1a including groove regions and non-groove regions is placed at a lower position on the drawings, and a second parent member 1b is placed on top of the first parent member 1a. In this case, the groove regions of the first parent member 1a and the protrusion regions of the second parent member 1b are located in an opposed relationship, while the non-groove regions of the first parent member 1a and the non-protrusion regions of the second parent member 1b are located in an opposed relationship.

Then, the second parent member 1b is fitted to the first parent member 1a, and contact junctions are formed thereby. Then, as shown in FIG. 6B, friction stir welding is performed along the contact junctions to from weld zones w. Each of the weld zones w is formed to remove at least a part of a horizontal interface between each of the hollow channels 200 and each of the holes 4. In this case, the weld zone w may be formed larger in width than each of grooves 2 of the first parent member 1a and each of protrusions 7 of the second parent member 1b. In addition, the weld zone w may be formed such that the depth thereof reaches a position below the horizontal interface between each of the hollow channels 200 and each of the holes 4, without exceeding the height of the protrusion 7 of the second parent member 1b. As a result, it is possible to prevent the problem that particles in the weld zones w are introduced through non-weld areas, causing a functional error of the hollow channels 200.

The weld zones W may be formed with the width and depth as above. The range of each of the weld zones W may include left and right contact junctions, the left contact junction being formed on at least a part of a left interface between a left contact surface (on the drawings) of each of the grooves 2 of the first parent member 1a and a left contact surface (on the drawings) of each of the protrusions 7 of the second parent member 1b, the right contact junction being formed on at least a part of a right interface between a right contact surface (on the drawings) of the groove 2 of the first parent member 1a and a right contact surface (on the drawings) of the protrusion 7 of the second parent member 1b. Due to this, each of the weld zones w removes at least a part of each of the left and right interfaces between each of the grooves 2 of the first parent member 1a and each of the protrusions 7 of the second parent member 1b. In addition, at least a part of the horizontal interface between each of the hollow channels 200 and each of the holes 4 is removed.

In the joined component 100 of the second modification of FIGS. 6A to 6D-2, the interval between the hollow channels 200 is relatively large and thus overlap portions 11 are not formed, but the holes 4 are formed between the hollow channels 200. However, when the grooves 2 of the groove regions of the first parent member 1a and the height of the protrusions 7 of the protrusion regions of the second parent member 1b are large, contact junctions may have a large depth. In this case, a shoulder 10a and a pin 10b of a welding tool 10 performing friction stir welding may be deeply inserted to form weld zones w.

After friction stir welding is performed along the contact junctions between the parent members 1 to form the weld zones w, a process of planarizing the weld zones w may be performed. At least a part of each of the weld zones w may be planarized.

As shown in FIG. 6C-1, planarizing may be performed at a position above the horizontal interfaces between the parent members 1, the position being indicated by a dotted line. In other words, planarizing may be performed above the horizontal interfaces between the parent members 1.

Then, the holes 4 vertically passing through the parent members 1 may be formed between the hollow channels 200 to obtain a joined component 100 having a shape as shown in FIG. 6D-1.

Alternatively, as shown in FIG. 6C-2, planarizing may be performed at a position below the horizontal interfaces between the parent members 1, the position being indicated by the a dotted line, within a range that does not deviate from the positions of the weld zones w, with respect to a downward direction on the drawings. In other words, planarizing may be performed below the horizontal interfaces between the parent members 1. A planarizing surface along which planarizing is performed may be located between the depth of the weld zones w and the horizontal interfaces. Then, the holes 4 vertically passing through the parent members 1 are formed between the hollow channels 200 to obtain a joined component 100 having a shape as shown in FIG. 6D-2.

In FIG. 6D-1, horizontal interfaces exist between the holes 4 and the hollow channels 200.

On the contrary, in the structure of FIG. 6D-2, unlike FIG. 6D-1, no horizontal interface exists between the holes 4 and the hollow channels 200. As a result, it is possible to prevent the problem of particle generation that may occur at the horizontal interfaces.

Due to the fact that each of the weld zones w is formed to remove at least a part of the horizontal interface between each of the hollow channels 200 and each of the holes 4, it is ensured that adverse interaction which may occur between the holes 4 and the hollow channels 200 is prevented by the weld zones W. In other words, movement of the fluid passing through the holes 4 to the hollow channels 200 along the interfaces between the parent members 1 is blocked by the weld zones w. As a result, it is ensured that the temperature control means provided in the hollow channels 200 is protected against adverse influence due to interaction between the hollow channels 200 and the holes 4, thus effectively performing the function thereof. Furthermore, formation of the weld zones W results in a non-weld area. The non-weld area is formed in at least a part between the contact surfaces of each of the grooves 2 of the first parent member 1a and the contact surfaces of each of the protrusions 7 of the second parent member 1b. This ensures that the contact area A between the temperature control means and the first parent member 1a increases and thus the temperature control function is further improved. As a result, it is possible to provide a joined component 100 having a uniform temperature, with minimized deformation.

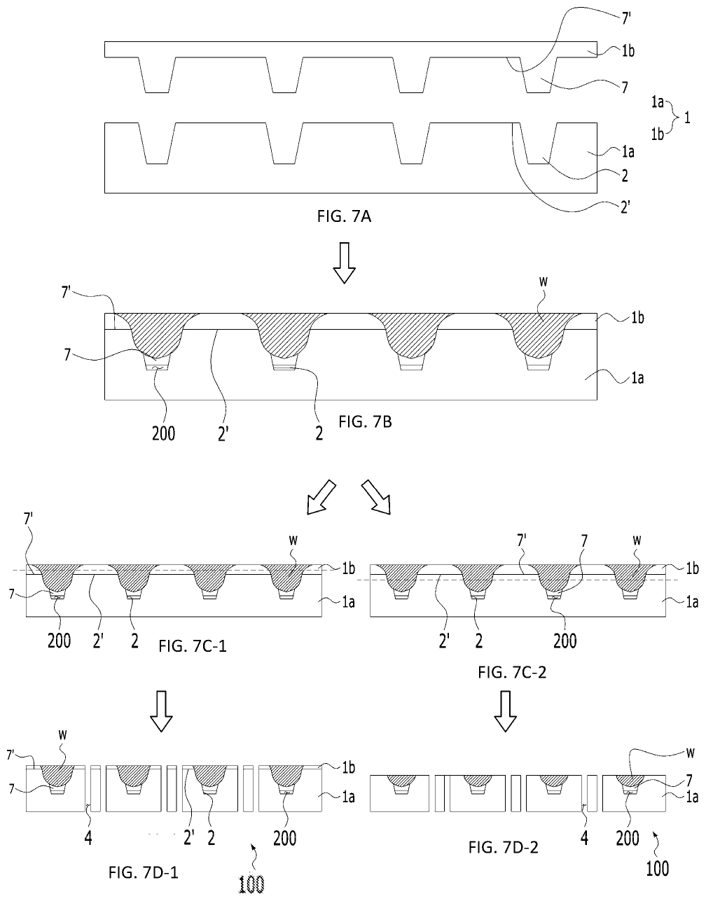

FIGS. 7A to 7D-2 are views schematically showing a manufacturing process of a joined component 100 according to second modification of the second embodiment. The joined component 100 according to the second modification differs from the second embodiment in that at least two holes 4 are formed between each of multiple hollow channels 200, without forming overlap portions 11.

The joined component 100 according to the second modification may include the multiple hollow channels 200 formed therein, and each of the hollow channels 200 may include a temperature control means. Furthermore, at least two holes 4 may be formed between each of the hollow channels 200. The holes 4 vertically pass through parent members 1 and provide passages through which a process fluid passes. In this case, the holes 4 may be arranged in a spaced apart relationship at an interval of equal to or greater than 3 mm to equal to or less than 15 mm. Hereinafter, the manufacturing process of FIG. 7 will be described in detail.

First, as shown in FIG. 7A, a first parent member 1a including groove regions and non-groove regions located at a lower position on the drawings is placed, and a second parent member 1b is placed on top of the first parent member 1a. In this case, the groove regions of the first parent member 1a and the protrusion regions of the second parent member 1b are located in an opposed relationship, while the non-groove regions of the first parent member 1a and the non-protrusion regions of the second parent member 1b are located in an opposed relationship.

Then, the second parent member 1b is fitted to the first parent member 1a, and contact junctions are formed thereby. Then, as shown in FIG. 7B, friction stir welding is performed along the contact junctions to from weld zones w. Each of the weld zones w is formed to remove at least a part of a horizontal interface between each of the hollow channels 200 and each of the holes 4. In this case, the weld zone w may be formed larger in width than each of grooves 2 of the first parent member 1a and each of protrusions 7 of the second parent member 1b. In addition, the weld zone w may be formed such that the depth thereof reaches a position below the horizontal interface between each of the hollow channels 200 and each of the holes 4, without exceeding the height of the protrusion 7 of the second parent member 1b. As a result, it is possible to prevent the problem that particles in the weld zones w are introduced through non-weld areas, causing a functional error of the hollow channels 200.

The weld zones W may be formed with the width and depth as above. The range of each of the weld zones W may include left and right contact junctions, the left contact junction being formed on at least a part of a left interface between a left contact surface (on the drawings) of each of the grooves 2 of the first parent member 1a and a left contact surface (on the drawings) of each of the protrusions 7 of the second parent member 1b, the right contact junction being formed on at least a part of a right interface between a right contact surface (on the drawings) of the groove 2 of the first parent member 1a and a right contact surface (on the drawings) of the protrusion 7 of the second parent member 1b. Due to this, each of the weld zones w removes at least a part of each of the left and right interfaces between each of the grooves 2 of the first parent member 1a and each of the protrusions 7 of the second parent member 1b. In addition, at least a part of the horizontal interface between each of the hollow channels 200 and each of the holes 4 is removed.

After friction stir welding is performed along the contact junctions of the parent members 1 to form the weld zones w, a process of planarizing the weld zones w may be performed. At least a part of each of the weld zones w may be planarized.

As shown in FIG. 7C-1, planarizing may be performed at a position above the horizontal interfaces between the parent members 1, the position being indicated by a dotted line. In other words, planarizing may be performed above the horizontal interfaces between the parent members 1.

Then, at least two holes 4 vertically passing through the parent members 1 may be formed between each of the hollow channels 200 to obtain a joined component having a shape as shown in FIG. 7D-1. In this case, the holes 4 may be arranged in a spaced apart relationship at an interval of equal to or greater than 3 mm to equal to or less than 15 mm. When the interval between the holes 4 is too large, the temperature control function of the temperature control means provided in the hollow channels 200 may be degraded. On the contrary, when the interval between the holes 4 is too small, it may be difficult to provide the temperature control means in the hollow channels 200. This is why it is preferable that the interval between the holes 4 is equal to or greater than 3 mm to equal to or less than 15 mm. By forming the holes 4 at the above interval, it is ensured that uniformity of the temperature of the joined component 100 is further improved.

Alternatively, as shown in FIG. 7C-2, planarizing may be performed at a position below the horizontal interfaces between the parent members 1, the position being indicated by a dotted line, within a range that does not deviate from the positions of the weld zones w, with respect to a downward direction on the drawings. In other words, planarizing may be performed below the horizontal interfaces between the parent members 1. A planarizing surface along which planarizing is performed may be located between the depth of the weld zones w and the horizontal interfaces. Then, at least two holes 4 vertically passing through the parent members 1 may be formed between each of the hollow channels 200 to obtain a joined component having a shape as shown in FIG. 7D-2.

In FIG. 7D-1, horizontal interfaces exist between the holes 4 and the hollow channels 200.

On the contrary, in the structure of FIG. 7D-2, unlike FIG. 7D-1, no horizontal interface exists between the holes 4 and the hollow channels 200. As a result, it is possible to prevent the problem of particle generation that may occur at the horizontal interfaces.

Due to the fact that each of the weld zones w is formed to remove at least a part of the horizontal interface between each of the hollow channels 200 and each of the holes 4, it is ensured that adverse interaction which may occur between the holes 4 and the hollow channels 200 is prevented by the weld zones W. In other words, movement of the fluid passing through the holes 4 to the hollow channels 200 along the interfaces between the parent members 1 is blocked by the weld zones w. As a result, it is ensured that the temperature control means provided in the hollow channels 200 is protected against adverse influence, thus effectively perform the function thereof. Furthermore, formation of the weld zones W results in a non-weld area. The non-weld area is formed in at least a part between the contact surfaces of each of the grooves 2 of the first parent member 1a and the contact surfaces of each of the protrusions 7 of the second parent member 1b. This ensures that the contact area A between the temperature control means and the first parent member 1a increases and thus the temperature control function is further improved. As a result, it is possible to provide a joined component 100 having a uniform temperature, with minimized deformation.

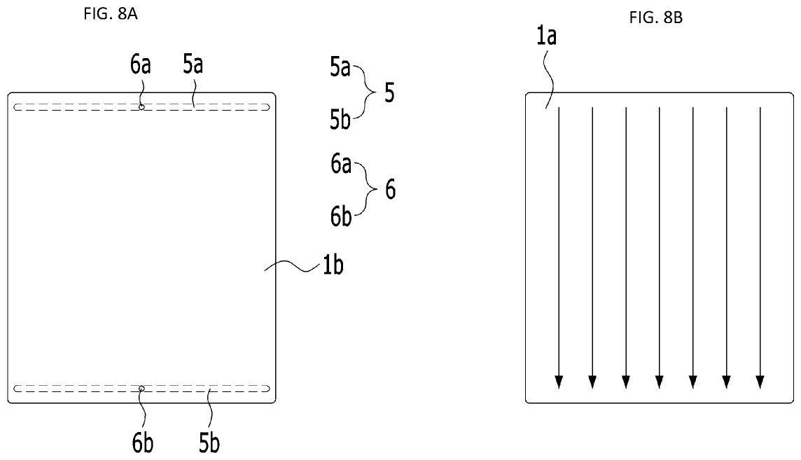

FIGS. 8A and 8B are views showing a direction of the flow of cooling or heating fluid when the hollow channels 200 have a one-layer structure as in the joined components of the first and second embodiments and a temperature control medium such as cooling or heating fluid as a temperature control means is provided in the hollow channels 200. Prior to describing the flow of the cooling or heating fluid, a description will be given of the shape of the configuration in which the temperature control medium such as cooling or heating fluid as the temperature control means is provided in the second parent member 1b.

As described above, each of the hollow channel 200 may include the temperature control means.

When the temperature control medium is provided as the temperature control means, the temperature control medium may move inside the joined component 100 through the hollow channels 200. In this case, the second parent member 1b may include a main hole 6 formed therein to provide a passage through which the temperature control medium is injected into the hollow channels 200. The main hole 6 may vertically pass through the second parent member 1b, while vertically passing through a communication groove 5 which will be described later. The second parent member 1b may include the communication groove 5 formed along the horizontal interfaces so as to cross the groove regions. The communication groove 5 may be formed to intersect with the groove regions at each of opposite positions corresponding to first and second ends of the groove regions are located. Referring to FIGS. 8A to 8B, the member shown in FIG. 8A is the second parent member 1b. The second parent member 1b may include the communication grooves 5 and the main holes 6. The communication grooves 5 may be formed in a contact surface of the second parent member 1b so as to cross the groove regions. The communication grooves 5 may be formed at upper and lower sides (on the drawings) of the second parent member 1b at respective opposite positions corresponding to the first and second ends of the groove regions. The communication groove 5 formed at the upper side of the contact surface of the second parent member 1b corresponding to the first ends of the groove regions intersect with the uppermost portions of the groove regions. The communication groove 5 formed at the lower side of the contact surface of the second parent member 1b corresponding to the second ends of the groove regions intersect with the lowermost portions of the groove regions. As such, the groove regions may be located between the communication grooves 5 at the upper and lower sides of the contact surface of the second parent member 1b, while communicating with the communication grooves 5. The main holes are formed to vertically pass through the second parent member 1b, while vertically passing through the communication grooves 5. Accordingly, the main holes 6 may vertically pass through the second parent member 1b at the upper and lower sides of the second parent member 1b, respectively.

Hereinafter, the flow of cooling or heating fluid when the hollow channels 200 has a one-layer structure as in the joined component 100 of the first embodiment will be described with reference to FIGS. 8A to 8B.

FIG. 8A is a view showing the second parent member 1b from above, and FIG. 8B is a view showing the direction of the flow of cooling or heating fluid in the first parent member 1a, indicated by an arrow.

As shown in FIG. 8A, the communication grooves 5 may be formed at the upper and lower sides of the contact surface of the second parent member 1b, and the main holes 6 passing through the second parent member 1b may be formed at positions where the communicating grooves 5 are formed. The communication grooves 5 may be formed to intersect with the groove regions of the first parent member 1a to communicate therewith the groove regions. The communication grooves 5 allow the cooling or heating fluid injected into the main holes 6 to be uniformly spread throughout the groove regions. This ensures that control of temperature inside the joined component 100 is realized.

The communication grooves 5 are comprised of a first communication groove 5a and a second communication groove 5b formed at the upper and lower sides of the contact surface of the second parent member 1b, respectively. Furthermore, the main holes 6 are comprised of a first main hole 6a passing through the first communication groove 5a, and a second main hole 6b passing through the second communication groove 5b. In this case, when the temperature control medium is injected into the first main hole 6a, the temperature control medium spreads through the entire groove regions through the first communication groove 5a, whereby the temperature inside the joined component 100 is controlled through the groove regions. As shown in FIG. 8B, the temperature control medium injected into the first main hole 6a may flow downward and be discharged through the second main hole 6b. The main holes 6 into which the temperature control medium is injected may be either of the first main hole 6a or the second main hole 6b. Depending on the position where the temperature control medium is injected, the flow of the fluid may be a downward flow or upward flow. Due to such unidirectional flow of the temperature control medium, it is possible to obtain an effect of controlling the temperature inside the joined component 100.

Alternatively, injection and discharge of the temperature control medium through the first main hole 6a and the second main hole 6b may be performed alternately. For example, a process of injecting the temperature control medium into the first main hole 6a and discharging the medium through the second main hole 6b may be performed, and then a process of injecting the medium into the second main hole 6b and discharging the medium through the first main hole 6a may be performed. These processes may be repeatedly performed. On the other hand, the main holes 6 and the communication grooves 5 may be suitably modified to allow alternating flows of the temperature control medium such as cooling or heating fluid to simultaneously occur. Due to the temperature control medium that horizontally alternately moves through the hollow channels 200, the temperature inside the joined component 100 is controlled.

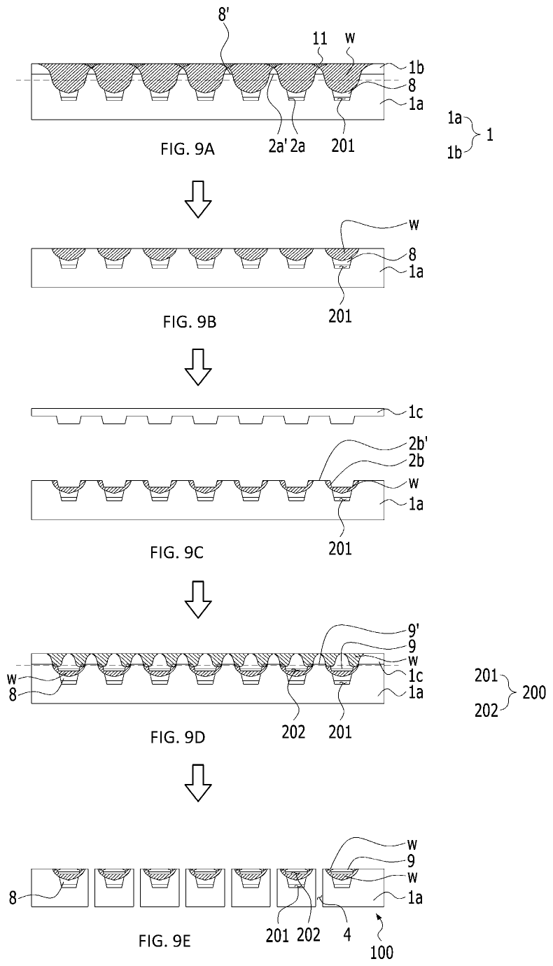

FIGS. 9A to 9E are views schematically showing a manufacturing process of a joined component 100 of a third embodiment of the present invention. The joined component 100 of the third embodiment differs from the first and second embodiments in that the number of parent members 1 and the shape of a portion of the parent members 1 are different, while hollow channels 200 formed inside the joined component 100 have a multi-layer structure. In the third embodiment, similarly to the first embodiment, a second parent member 1b is stacked on top of a first parent member 1a. In addition, a third parent member 1c is stacked on top of the second parent member 1b. The third parent member 1c includes second protrusion regions where second protrusions 9 are formed and second non-protrusion regions 9′ where second protrusions 9 are not formed. In this case, the shape of the parent members 1 and the shape in which the parent members 1 are stacked are described as an example only, and are not limited thereto. The parent members 1 may have a shape suitable for forming hollow channels 200 and for controlling the temperature inside the hollow channels 200 by use of cooling or heating fluid (liquid or gas) that moves therethrough.

The joined component 100 of the third embodiment may include: a first parent member 1a including first groove regions in which first grooves 2a are formed and first non-groove regions 2a′ in which the first groove 2a are not formed; a second parent member 1b including first protrusion regions in which first protrusions 8 are formed and first non-protrusion regions 8′ in which the first protrusion 8 are not formed; and a third parent member 1c including second protrusion regions in which second protrusions 9 are formed and second non-protrusion regions 9′ in which the second protrusions 9 are not formed. The joined component 100 may further include: first and second hollow channels 201 and 202 formed therein and each includes a temperature control means; and holes 4 vertically passing through the parent members 1 and providing passages through which a process fluid passes.

When at least three parent members 1 are provided and these parent members 1 are stacked on top of each other and welded by friction stir welding as in the joined component 100 of the third embodiment, at least two parent members 1 (for example, the first and second parent members 1a and 1b) are first welded by friction stir welding, and then a remaining one of the parent members 1 (for example, the third parent member 1c) may be welded by friction stir welding to the welded parent members 1a and 1b. In this case, at least two parent members 1a and 1b to be friction stir welded first are not limited, as long as at least two parent members of at least three parent members 1 are first welded by friction stir welding and then a remaining one of the parent members 1 is welded by friction stir welding to the welded parent members 1. Hereinafter, a description is given of an example in which the first parent member 1a and the second parent member 1b placed on top of the first parent member 1a are first welded by friction stir welding, and then the third parent member 1c is welded by friction stir welding to the welded first and second parent members 1a and 1b.

First, as shown in FIG. 9A, the second parent member 1b is fitted to the first parent member 1a, and then friction stir welding is performed along contact junctions to form weld zones W. In this case, the joined component 100 of the third embodiment is described as an example that the hollow channels 200 are arranged at a relatively small interval, resulting in formation of overlap portions 11 where the weld zones W overlap each other. However, the overlap portions 11 may not be formed.

After the weld zones w are formed by friction stir welding the first and second parent members 1a and 1b, planarizing may be performed at a position indicated by a dotted line shown in FIG. 9A. In other words, the dotted line may indicate the position of a planarizing surface along which planarizing is performed. Planarizing may be performed above the horizontal interfaces between the parent members 1. Alternatively, as shown in FIG. 9A, planarizing may be performed below the horizontal interfaces between the parent members 1. As a result, as shown in FIG. 9B, the first and second parent members 1a and 1b welded by friction stir welding has a shape in which the interfaces between the first and second parent members 1a and 1b are removed, with each of the weld zones w present on at least a part of each of the contact junctions.

At least a part of each of the weld zones w of the first and second parent members 1a and 1b welded by friction stir welding is planarized, and the horizontal interfaces between the first and second parent members 1a and 1b are removed thereby. As a result, as shown in FIG. 9B, the first parent member 1a has a shape having a first-layer hollow channel 201 formed by at least a part of each of the weld zones w, at least a part of each of the protrusions 8 of the second parent member 1b, and by engagement of the first and second members 1a and 1b fitted together. In the first-layer hollow channel 201, introduction of function disturbances such as particles that move along the interfaces between the parent members 1a and 1b is blocked by the weld zone w. This ensures that the function of the temperature control means provided in the first-layer hollow channel 201 is performed more effectively. In addition, due to non-weld areas, the contact area A between the temperature control means and the first parent member 1a increases, thus ensuring that a temperature control function is further improved.

Then, as shown in FIG. 9C, a second groove 2b is formed in at least a part of each of the weld zones w from which at a least a part is planarized. The second groove 2b may be formed in at least a part of the weld zone w, within a range of the weld zone w. In a region where the second groove 2b is not formed, each of the second non-groove regions 2b is formed. The second groove 2b formed in at least a part of the weld zone w may be located at a position corresponding to each of the second protrusions 9 of the third parent member 1c.

Then, as shown in FIG. 9C, the third parent member 1c including the second protrusions 9 is fitted. In detail, each of the second protrusions 9 of the third parent members 1c may be fitted into the second groove 2b formed in at least a part of the weld zone w. This results in formation of a second-layer hollow channel 202. The second-layer hollow channel 202 formed by the second groove 2b formed within the range of the weld zone w may have a shape surrounded by at least a part of the weld zone w.

Then, as shown in FIG. 9D, friction stir welding may be performed along contact junctions formed when the second protrusion 9 of the third parent member 1c is fitted into the second groove 2b. In this case, in FIG. 9D, friction stir welding is performed along a left contact junction (on the drawings) formed on at least a part of a left interface and along a right contact junction (on the drawings) formed on at least a part of right left interface, such that a weld zone w is formed on each of the left and right contact junctions. However, the weld zones w may be formed as one weld zone W having a range within which the left and right contact junctions are included. The one weld zone W may be larger in width than the second protrusion 9 and the second groove 3 of the third parent member 1c.

As shown in FIG. 9D, in the second-layer hollow channel 202, due to at least a part of the weld zone W surrounding the second-layer hollow channel 202, and due to the weld zones W formed on the left and right contact junctions, adverse influence which may occur due to particles that move along the interface between the parent members 1 is prevented. This ensures that the function of the temperature control means provided in the second-layer hollow channel 202 is performed more effectively. In addition, due to non-weld areas, the contact area A between the temperature control means moving through the second-layer hollow channel 202 and the parent members 1 increases, thus ensuring that a temperature control function is further improved.

As shown in FIG. 9D, after the second protrusion 9 of the third parent member 1c is fitted into the second groove 2b and welded by friction stir welding, secondary planarizing may be performed. When a process shown in FIG. 9B is referred to as primary planarizing, secondary planarizing is performed as shown in FIG. 9D. The second parent member 1c is welded to the planarized first and second parent members 1a and 1b by friction stir welding, and weld zones w formed thereby are planarized. The secondary planarizing may be performed at the same position as the dotted line shown in FIG. 9D. In other words, the dotted line may indicate the position of a planarizing surface along which planarizing is performed. Planarizing may be performed above the horizontal interfaces between the parent members 1. Alternatively, as shown in FIG. 9D, planarizing may be performed below the horizontal interfaces between the parent members 1. Due to this, the interfaces between the first parent and third parent members 1a and 1c welded by friction stir welding may be removed. As a result, it is possible to prevent the problem of particle generation that may occur at the horizontal interfaces.

Then, as shown in FIG. 9E, holes 4 vertically passing through the parent members 1 are formed between the hollow channels 200 to obtain a joined component 100.

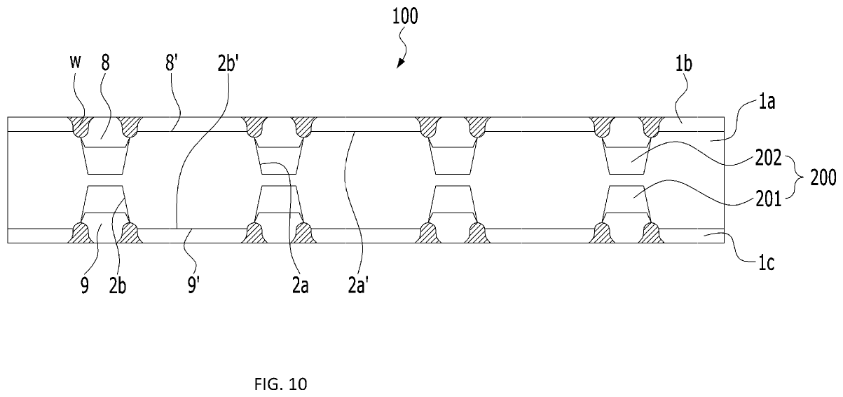

FIG. 10 is a view showing a modification of the joined component 300 according to the third embodiment of the present invention. A joined component 100 of the modification of the third embodiment differs from the third embodiment in that the shape of a portion of parent members 1 is changed. In the modification, similarly to the third embodiment, a second parent member 1b is stacked on top of a first parent member 1a. In addition, a third parent member 1c is stacked on bottom of the second parent member 1b. In this case, the shape of the parent members 1 and the shape in which the parent members 1 are stacked are described as an example only, but are not limited thereto. The parent members 1 may have a shape suitable for forming hollow channels 200 and for controlling the temperature inside the hollow channels 200 by use of cooling or heating fluid (liquid or gas) that moves therethrough. The grooves and the protrusions of the modification may differ from those of the parent members 1 of the third embodiment in that parent members 1 on which the groove and the protrusion are formed are different and formation positions are different. However, the same reference numerals are used for the sake of convenience.

The joined component 100 of the modification includes: a first parent member 1a including an upper contact surface (on the drawings) provided with first groove regions in which first grooves 2a are formed and first non-groove regions 2a′ in which the first grooves 2a are not formed, and a lower contact surface (on the drawings) provided with second groove regions in which second grooves 2b are formed and second non-groove regions 2b′ in which the second grooves 2b are not formed; a second parent member 1b including first protrusion regions in which first protrusions 8 are formed and first non-protrusion regions 8′ in which the first protrusion 8 are not formed; and a third parent member 1c including second protrusion regions in which second protrusions 9 are formed and second non-protrusion regions 9′ in which the second protrusions 9 are not formed. The joined component 100 may further include: first and second hollow channels 201 and 202 formed therein and each includes a temperature control means; and holes 4 vertically passing through the parent members 1 and providing passages through which a process fluid passes.

The first groove regions and the first non-groove regions of the first parent member 1a may be formed in the upper contact surface (on the drawings) of the first parent member 1a. Meanwhile, the second groove regions and the second non-groove regions of the first parent member 1a may be formed in the lower contact surface (on the drawings) of the first parent member 1a. This is only an example, but is not limited thereto. The positions of the contact surfaces where the first and second groove region and the first and second non-groove regions are formed may vary.

The first and second groove regions of the first parent member 1a, the first protrusion regions of the second parent member 1b, and the second protrusion regions of the third parent member 1c may be located at positions corresponding to each other. In this case, the first parent member 1a may be interposed between the second and third parent members 1b and 1c, with the second parent member 1b on top and the third parent member 1c on bottom. Accordingly, the first protrusion regions of the second parent member 1b and the second protrusion regions of the third parent member 1c may be located in an opposed relationship, with the first and second groove regions of the first parent member 1a interposed therebetween.

When at least three parent members 1 are provided and these parent members 1 are stacked on top of each other and welded by friction stir welding as in the joined component 100 of the modification, at least two parent members 1 (for example, the first and second parent members 1a and 1b) are first welded by friction stir welding, and then a remaining one of the parent members 1 (for example, the third parent member 1c) may be welded by friction stir welding to the welded parent members 1a and 1b. In this case, at least two parent members 1a and 1b to be friction stir welded first are not limited, as long as at least two parent members of at least three parent members 1 are first welded by friction stir welding and then a remaining one of the parent members 1 is welded by friction stir welding to the welded parent members 1. Hereinafter, a description is given of an example in which the first parent member 1a and the second parent member 1b placed on top of the first parent member 1a are first welded by friction stir welding, and then the third parent member 1c is welded by friction stir welding to the welded first and second parent members 1a and 1b.

A weld zone W may be formed at the joined component 100 by friction stir welding. In this case, the weld zone w may be formed to remove at least a part of a horizontal interface between each of the hollow channels 200 and each of the holes 4. As shown in FIG. 10, multiple weld zones w are formed at the joined component 100. The weld zones w may be formed on contact junctions of the parent members 1.

First, the second parent member 1b is fitted to the first parent member 1a, and the contact junctions are formed thereby. In this case, each of the first protrusions 8 of the second parent member 1b is fitted into each of the first grooves 2a of the first parent member 1a while coming into contact with at least a part thereof, and contact junctions are formed thereby. As shown in FIG. 10, left and right contact surfaces (on the drawings) of the first protrusion 8 of the second parent member 1b in a width direction are brought into contact with left and right contact surfaces (on the drawings) of the first groove 2a of the first parent member 1a in a width direction, and left and right interfaces are formed therebetween. This results in formation of contact junctions. Each of the contact junctions is formed on at least a part of each of the left and right interfaces (on the drawings) between the first groove 2a of the first parent member 1a and the first protrusion 8 of the second parent member 1b. Friction stir welding may be performed along the contact junctions.

Friction stir welding is performed along a contact junction formed on at least a part of the left interface (on the drawings) to form a weld zone w, and along a contact junction formed at least a part of the right interface (on the drawings) to form a weld zone w. In other words, a weld zone w may be formed on at least a part of a left contact junction (on the drawings) and on at least a part of a right contact junction (on the drawings). In this case, the weld zone w may be formed such that the depth thereof reaches a position below the horizontal interface between the hollow channel 200 and the hole 4, without exceeding the height of the first protrusion 8 of the second parent member 1b. As a result, each of the weld zones w formed on the contact junctions of the first and second parent members 1a and 1b removes at least a part of each of the left and right interfaces (on the drawings) between each of the first grooves 2a of the first parent member 1a and each of the first protrusions 8 of the second parent member 1b which are fitted together. The weld zone w also removes at least a part of each horizontal interface between the first and second parent members 1a and 1b.

Then, the third parent member 1c is placed on the bottom of the first parent member 1a and welded by friction stir welding. In this case, each of the second grooves 2b formed in the lower contact surface of the first parent member 1a is fitted into each of the second protrusions 9 of the third parent member 1c while coming into contact therewith at least a part thereof, and contact junctions are formed thereby. As shown in FIG. 10, left and right contact surfaces (on the drawings) of the first protrusion 8 of the second parent member 1b in a width direction are brought into contact with left and right contact surfaces (on the drawings) of the first groove 2a of the first parent member 1a in a width direction, and left and right interfaces are formed therebetween. This results in formation of contact junctions. Each of the contact junctions is formed on at least a part of each of the left and right interfaces (on the drawings) between the second groove 2b of the first parent member 1a and the second protrusion 9 of the second parent member 1b. Friction stir welding may be performed along the contact junctions.

Friction stir welding is performed along a contact junction formed on at least a part of the left interface (on the drawings) to form a weld zone w, and along a contact junction formed at least a part of the right interface (on the drawings) to form a weld zone w. In other words, a weld zone w may be formed on at least a part of a left contact junction (on the drawings) and on at least a part of a right contact junction (on the drawings). In this case, the weld zone w may be formed such that the depth thereof reaches a position below the horizontal interface between the hollow channel 200 and the hole 4, without exceeding the height of the second protrusion 9 of the third parent member 1c. As a result, each of the weld zones w formed on the contact junctions of the first and third parent members 1a and 1c removes at least a part of each of the left and right interfaces (on the drawings) between each of the second grooves 2b of the first parent member 1a and each of the second protrusions 9 of the third parent member 1c which are fitted together. The weld zone w also removes at least a part of each horizontal interface between the first and second parent members 1a and 1b. Then, a process of planarizing top and bottom surfaces is performed.

The formation of the weld zones W on the contact junctions results in formation of non-weld areas. Due to the non-weld areas, the contact area A between the temperature control means and the parent members 1 increases in a hollow channel 200 including first and second hollow channels 201 and 202 which will be described later, thus ensuring that uniformity of the temperature of the joined component 100 is secured more effectively.

The holes 4 which provide passages through which the process fluid passes may be formed in the parent members 1. The holes 4 may be formed by vertically passing through the parent members 1. In this case, due to the fact that each of the weld zones w is formed to remove at least a part of each of the left and right interfaces between each groove and each protrusion so as to remove at least a part of each horizontal interface between the first and second parent members 1a and 1b, the weld zone w may exist between each of the hollow channels 200 and each of the holes 4. As a result, it is possible to prevent adverse interaction from occurring between the hollow channels 200 and the holes 4, thus preventing a functional error of the joined component 100.

In the joined component 100 of the modification of the third embodiment shown in FIG. 10, each of the weld zones w is formed at each of the left and right interfaces between each groove and each protrusion so as to remove at least a part of each of the left and right interfaces while removing at least a part of each horizontal interface between the first and second parent members 1a and 1b. However, this is only an example, and the present invention is not limited thereto.

As shown in FIGS. 9A to 9E and FIG. 10, the joined component 100 of the third embodiment and the joined component 100 of the modification thereof may include the hollow channels 200 having a multi-layer structure. In detail, each of the hollow channels 200 may have a two-layer structure. In the joined component 100 including the hollow channel 200 having a multi-layer structure, depending on the shape in which the hollow channel 200 is formed in the joined component 100, a direction of the flow of a temperature control medium such as cooling or heating fluid (liquid or gas) that moves through the hollow channel 200 may vary.

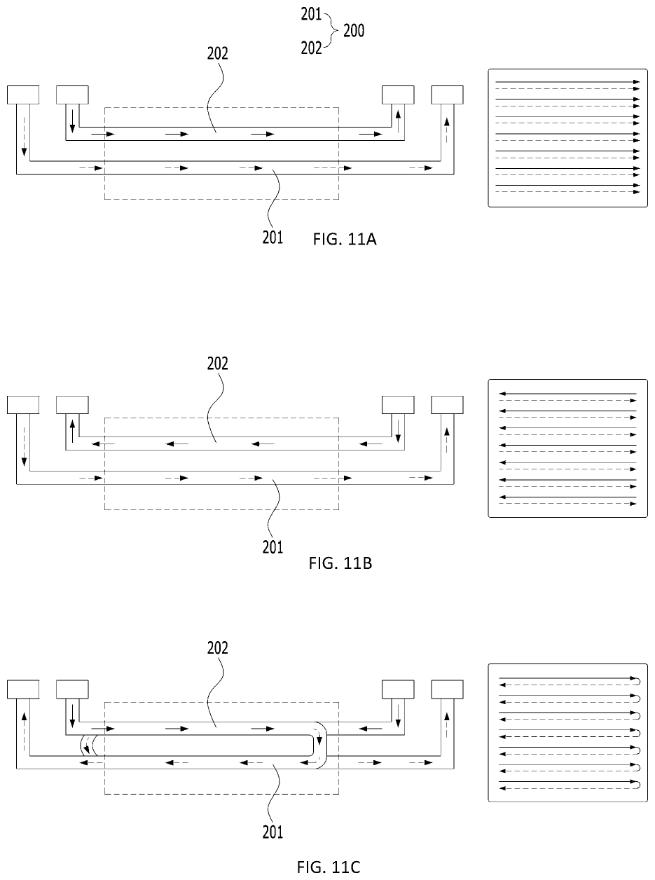

FIGS. 11A to 11C are views showing the direction of flow of cooling or heating fluid when the hollow channel 200 has a multi-layer structure as in the joined components 100 of the third embodiment and the modification of the third embodiment. In this case, the first-layer hollow channel 201 includes the first groove region in which the first groove 2a of the first parent member 1a is formed, and the second-layer hollow channel 202 includes the second groove region in which the second groove 2b of the second parent member 1b is formed.

In FIG. 11A, a left view is a sectional view showing the hollow channel 200 having a two-layer structure, and a right view is a plan view showing a direction of the flow of cooling or heating fluid when the hollow channel 200 having a two-layer structure as shown in the left view of FIG. 11A is formed.

As shown in the left view of FIG. 11A, when the hollow channel 200 having a two-layer structure is comprised of the first-layer hollow channel 201 and the second-layer hollow channel 202 formed inside the joined component 100, the cooling or heating fluid may move in the same one direction in each of the first- and second-layer hollow channels 201 and 202 through the hollow channel 200. In the right view of FIG. 11A, a dashed arrow may indicate a direction of the flow of cooling or heating fluid in the first-layer hollow channel 201, and a solid arrow may indicate a direction of the flow of cooling or heating fluid in the second-layer hollow channel 202. Accordingly, as shown in the left view of FIG. 11A, when the first- and second-layer hollow channels 201 and 202 are formed in respective layers inside the joined component 100, the cooling or heating fluid may move in each layer in the same direction to make the temperature of the joined component 100 uniform. In this case, one direction in which the cooling or heating fluid flows may a direction opposite to the direction shown in FIG. 11A.

In the left view of FIG. 11A, when the first- and second-layer hollow channels 201 and 202 are paired, a first-first-layer hollow channel 200 and a second-first-layer hollow channel 200 may exist adjacent to the first- and second-layer hollow channels 201 and 202. In this case, in the first-first-layer hollow channel 200 and the second-first-layer hollow channel 200 existing adjacent to the first- and second-layer hollow channels 201 and 202, the cooling or heating fluid may flow in a direction opposite to the direction of the flow of cooling or heating fluid in the first- and second-layer hollow channels 201 and 202, whereby alternating flows are generated in two-dimensions. Due to such an alternating flow, it is ensured that the temperature of the joined component 100 is controlled to be uniform.

As shown in a left view of FIG. 11A, when the hollow channel 200 having a two-layer structure is comprised of the first-layer hollow channel 201 and the second-layer hollow channel 202 formed inside the joined component 100, as shown in a right view of FIG. 11B, the cooling or heating fluid in the first-layer hollow channel 201 and the cooling or heating fluid in the second-layer hollow channel 202 may flow in opposite directions. For example, as shown in the right view of FIG. 11B, a dashed arrow indicates a direction of the flow of cooling or heating fluid in the first-layer hollow channel 201, and a solid arrow indicates a direction of the flow of cooling or heating fluid in the second-layer hollow channel 202. In this case, when the cooling or heating fluid in the first-layer hollow channel 201 flows from left to right, the cooling or heating fluid in the second-layer hollow channel 202 may flow right to left. Due to such opposite flows of the cooling of heating fluid for temperature control flowing in each of the first- and second-layer hollow channels 201 and 202, it is ensured that the temperature of the joined component 100 is controlled more uniformly.

In FIG. 11C, a left view shows that the joined component 100 including the hollow channel 200 having a two-layer structure in which the first- and second-layer hollow channels 201 and 202 are formed to communicate with each other, and a right view shows the flow of cooling or heating fluid in this case. As shown in FIG. 11C, the cooling or heating fluid may flow in a U-turn in an area where the first- and second-layer hollow channels 201 and 202 communicate with each other and make a flow opposite to the flow of cooling or heating fluid in one hollow channel 200. In other words, when multi-layer hollow channels 200 are formed inside the joined part 100 so as to communicate with each other, the flow of cooling or heating fluid of at least one of the hollow channels 200 makes a U-turn in a communication area to flow through a remaining one of the hollow channels 200. Due to the hollow channel 200 having a two-layer structure as described above, it is ensured that uniformity of the temperature of the joined component 100 is secured.

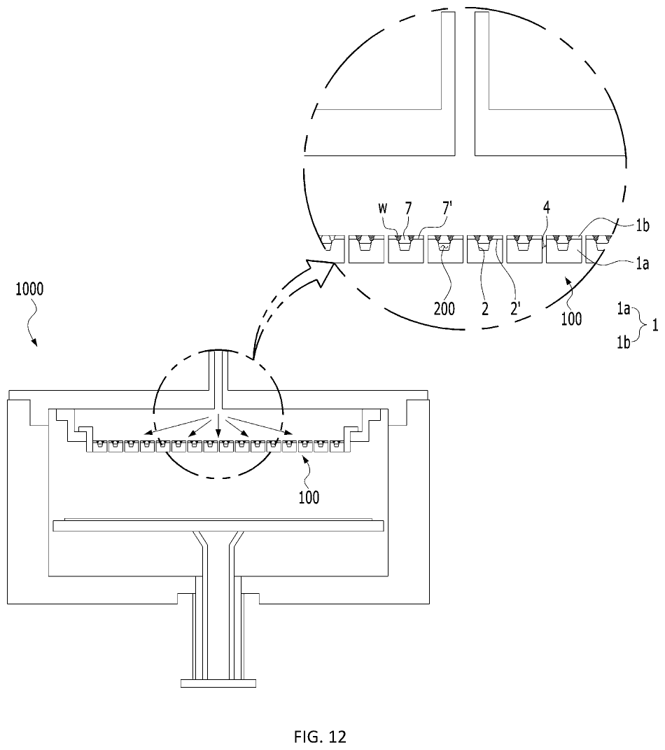

FIG. 12 is a view schematically showing semiconductor manufacturing process equipment 1000 including the joined component 100 according to the first embodiment of the present invention. In this case, shown that the joined component 100 of the first embodiment is provided. However, the joined components 100 of the second and third embodiments and modifications may be possible.

As shown in FIG. 12, the joined component 100 may constitute the semiconductor manufacturing process equipment 1000. The semiconductor manufacturing process equipment 1000 may be used in a process of manufacturing a part of components of a semiconductor by using a fluid supplied through the holes 4 of the joined component 100. The semiconductor manufacturing process equipment 1000 includes etching equipment, cleaning equipment, heat treatment equipment, ion implantation equipment, sputtering equipment, CVD equipment, and the like which will be described below.

The joined component 100 includes the hollow channels 200 formed in the contact surfaces of the parent members 1 by extending therealong and including the temperature control means provided therein, and the holes 4 vertically passing through the parent members 1. The weld zones w by friction stir welding are formed such that each of the weld zones w removes at least a part of the horizontal interface between each of the hollow channels 200 and each of the holes 4. This prevents adverse influence that may occur between the hollow channels 200 and the holes 4.

The temperature control means provided in the joined component 100 may be a fluid including cooling fluid or heating fluid, or a heating wire. The joined component 100 controls temperature by performing a cooling function or a heating function depending on the temperature control means. As a result, it is possible to minimize deformation of the joined component 100.

The semiconductor manufacturing process equipment including the joined component 100 may be etching equipment. The etching equipment including the joined component 100 may be used to pattern a portion on a wafer using a process fluid passing through the holes 4 of the joined component 100. The etching equipment may be wet etching equipment, dry etching equipment, plasma etching equipment, or reactive ion etching (RIE) equipment. When the semiconductor manufacturing process equipment including the joined component 100 is etching equipment, the joined component 100 supplies a process fluid for an etching process to a workpiece. The process fluid passes through the holes 4. In this case, the weld zones w by friction stir welding are formed such that each of the weld zones w removes at least a part of the horizontal interface between each of the hollow channels 200 and each of the holes 4. This prevents the process fluid passing through the holes 4 from leaking into the hollow channels 200. The hollow channels 200 in which adverse influence is prevented by the weld zones w can secure uniformity of the temperature of the joined component 100 using the temperature control means provided therein, thus minimizing deformation. In the joined component 100, adverse interaction which may occur between the hollow channels 200 and the holes 4 is prevented by the weld zones w, and thus a functional error of the joined component 100 is prevented.

The semiconductor manufacturing process equipment including the joined component 100 may be cleaning equipment. When the semiconductor manufacturing process equipment including the joined component 100 is cleaning equipment, the cleaning equipment including the joined component 100 may be used to clean particulate or chemical foreign substances that may cause defects in a manufacturing process, using a process fluid that passes through the holes 4. The cleaning equipment may be a cleaner or a wafer scrubber. The joined component 100 supplies a process fluid for a cleaning process to a workpiece. The process fluid passes through the holes 4. In this case, the weld zones w by friction stir welding are formed such that each of the weld zones w removes at least a part of the horizontal interface between each of the hollow channels 200 and each of the holes 4. This prevents the process fluid passing through the holes 4 from leaking into the hollow channels 200. As a result, it is ensured that the temperature control means provided in the hollow channels 200 effectively performs the function thereof and makes the temperature of the joined component 100 uniform to minimize deformation of a product.

The semiconductor manufacturing process equipment including the joined component 100 may be heat treatment equipment. When the semiconductor manufacturing process equipment including the joined component 100 is heat treatment equipment, the joined component 100 supplies a process fluid for a heat treatment process to a workpiece. The process fluid passes through the holes 4. In this case, the weld zones w by friction stir welding are formed such that each of the weld zones w removes at least a part of the horizontal interface between each of the hollow channels 200 and each of the holes 4. Due to this, the process fluid passing through the holes 4 is prevented from moving to the hollow channels 200 by the weld zones W. The hollow channels 200 in which adverse interaction with the holes 3 is prevented by the weld zones w can perform the function of securing uniformity of the temperature of the joined component 100 using the temperature control means provided therein. As a result, it is possible to minimize deformation of the joined component 100, while reducing a function error of the joined component 100.

The semiconductor manufacturing process equipment including the joined component 100 may be ion implantation equipment. When semiconductor manufacturing process equipment including the joined component 100 is ion implantation equipment, the joined component 100 supplies a process fluid for an ion implantation process to a workpiece through the holes 4. In this case, the weld zones w by friction stir welding are formed such that each of the weld zones w removes at least a part of the horizontal interface between each of the hollow channels 200 and each of the holes 4. This prevents adverse interaction between the holes 4 and the hollow channels 200. The adverse interaction may mean that the process fluid passing through the holes 4 leaks into the hollow channels 200 and adversely influences the temperature control means provided in the hollow channels 200. The hollow channels 200 are protected by the weld zones w in an isolated form to effectively control the temperature of the joined component 100 using the temperature control means provided therein. As a result, it is possible to obtain the effect of minimizing deformation of the joined component 100, while reducing a functional error thereof.

The semiconductor manufacturing process equipment including the joined component 100 may be sputtering equipment. When semiconductor manufacturing process equipment including the joined component 100 is sputtering equipment, the joined component 100 supplies the process fluid for a sputtering process to a workpiece through the holes 4. The joined component 100 includes the weld zones w by friction stir welding. The weld zones w are formed such that each of the weld zones w removes at least a part of the horizontal interface between each of the hollow channels 200 and each of the holes 4. This prevents the process fluid passing through the holes 4 from leaking into the hollow channels 200. As a result, it is ensured that the temperature control means provided in the hollow channels 200 effectively performs the function thereof and deformation of a product is minimized. In addition, it is possible to implement a joined component 100 having temperature uniformity.

The semiconductor manufacturing process equipment including the joined component 100 may be CVD equipment. The CVD equipment including the joined component 100 may be used to deposit a thin film on the surface of a wafer 200 by chemical reaction occurring in electrons or vapor phases by exciting a reaction process fluid composed of elements with energy, such as a thermal plasma discharge, photo-discharge, or the like. The CVD equipment may be atmospheric pressure CVD equipment, reduced pressure CVD equipment, plasma CVD equipment, photo-initiated CVD equipment, or MO-CVD equipment. When semiconductor manufacturing process equipment including the joined component 100 is CVD equipment, the joined component 100 may be a showerhead used in a semiconductor manufacturing process. The joined component 100 supplies a process fluid for a CVD process to a workpiece through the holes 4. In this case, the joined component 100 includes the weld zones w by friction stir welding. The weld zones w are formed such that each of the weld zones w removes at least a part of the horizontal interface between each of the hollow channels 200 and each of the holes 4. This prevents adverse interaction between the holes 4 and the hollow channels 200. The hollow channels 200 in which adverse interaction with the holes 3 is prevented by the weld zones w can secure uniformity of the temperature of the joined component 100 using the temperature control means provided therein. As a result, it is possible to obtain the effect of minimizing deformation of a product, while reducing a functional error thereof.

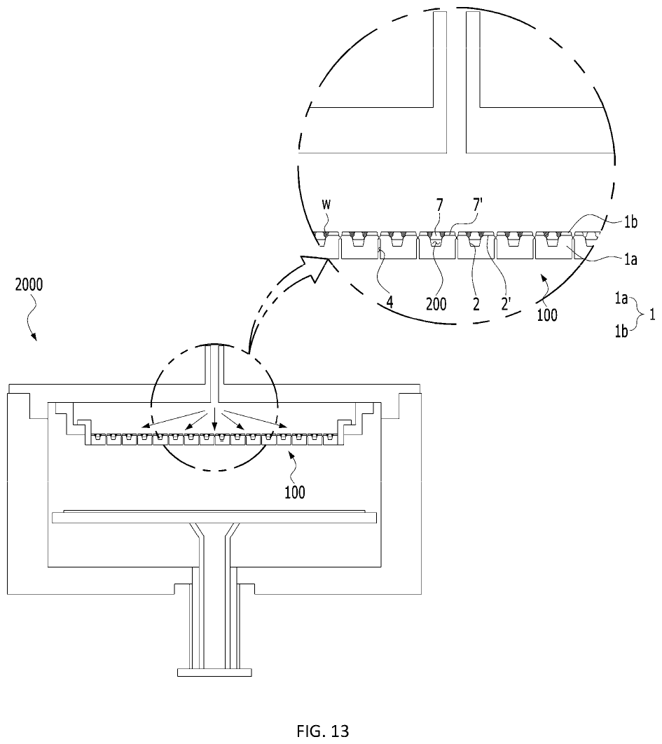

As shown in FIG. 13, the joined component 100 may constitute display manufacturing process equipment 2000. The display manufacturing process equipment 2000 may be used in a process of manufacturing a part of components of a display by using a fluid supplied through the holes 4 of the joined component 100. In this case, shown that the joined component 100 of the first embodiment is provided. However, the joined components 100 of the second and third embodiments and modifications may be possible. On the other hand, the joined component 100 constituting the display manufacturing process equipment 2000 differs from those of the first to third embodiments and modifications in terms of the shape of the holes 4. In this case, the holes 4 of the joined component 100 constituting the display manufacturing process equipment 2000 may have a different width for each position at which a process fluid passes. Although the holes 4 of the joined component 100 constituting the display manufacturing process equipment 2000 have a shape different from that of the holes 4 of the first to third embodiments and modifications described above, the shape of the holes 4 is not limited thereto. The function of the holes 4 through which the process fluid passes may be the same.

The display manufacturing process equipment 2000 includes etching equipment, cleaning equipment, heat treatment equipment, ion implantation equipment, sputtering equipment, CVD equipment, and the like. For example, the joined component 100 constituting CVD equipment may be a diffuser.

When the joined component 100 constitutes the display manufacturing process equipment 2000, a process fluid is supplied through the holes 4 in the same manner as the joined component 100 constituting the semiconductor manufacturing process equipment 1000 described above. In this case, the weld zones w by friction stir welding are formed such that each of the weld zones w removes at least a part of the horizontal interface between each of the hollow channels 200 and each of the holes 4. This prevents negative interaction between the holes 4 and the hollow channels 200. The hollow channels 200 in which adverse interaction with the holes 3 is prevented by the weld zones w can effectively control the temperature of the joined component 100 using the temperature control means provided therein. This ensures that uniformity of the temperature of the joined component 100 is secured, resulting in minimized deformation of a product. It is also ensured that when provided as one of the components of the display manufacturing process equipment 2000, a functional error is reduced, resulting in an increase in efficiency of a process.

The joined component 100 may constitute the semiconductor manufacturing process equipment 1000 or the display manufacturing process equipment 2000 as described above, and the effect obtained by the joined component 100 may be the same.

Although the exemplary embodiments of the present invention have been described for illustrative purposes, those skilled in the art will appreciate that various modifications, additions and substitutions are possible, without departing from the scope and spirit of the invention as disclosed in the accompanying claims.

What is claimed is:

1. A joined component through which a process fluid passes in a semiconductor manufacturing process or a display manufacturing process, the joined component being formed by joining at least two parent members by friction stir welding, and comprising:
a hollow channel formed inside the joined component and including a temperature control means; and
a hole vertically passing through the parent members and providing passages through which the process fluid passes,
a weld zone by friction stir welding is formed to remove at least a part of a horizontal interface between each of the hollow channels and each of the holes.

2. A joined component through which a process fluid passes in a semiconductor manufacturing process or a display manufacturing process, the joined component being formed by joining at least two parent members by friction stir welding, and comprising:
a hollow channel formed inside the joined component and including a temperature control means; and
a hole vertically passing through an overlap portion where weld zones by friction stir welding at least partially overlap each other,
wherein each of the weld zones by friction stir welding is formed to remove at least a part of a horizontal interface between the hollow channel and the hole.

3. The joined component of claim 1, wherein the weld zone by the friction stir welding is formed along the hollow channel.

4. The joined component of claim 1, wherein the temperature control means is a fluid.

5. The joined component of claim 1, wherein the temperature control means is a heat wire.

6. The joined component of claim 1, wherein the hole is provided as multiple holes that are arranged in a spaced apart relationship at an interval of equal to or greater than 3 mm to equal to or less than 15 mm.

7. The joined component of claim 1, wherein the joined component is provided in etching equipment, cleaning equipment, heat treatment equipment, ion implantation equipment, sputtering equipment, or CVD equipment.

8. A joined component through which a process fluid passes in a semiconductor manufacturing process or a display manufacturing process, the joined component being formed by joining at least two parent members by friction stir welding, and comprising:
multiple holes vertically passing through the parent members and providing passages through which the process fluid passes; and
a hollow channel provided between each of the holes and including a temperature control means,
wherein the holes are arranged in a spaced apart relationship at an interval of equal to or greater than 3 mm to equal to or less than 15 mm, and
a weld zone by friction stir welding is to remove at least a part of a horizontal interface between the hollow channel and each of the holes.

9. A joined component through which a process fluid passes in a semiconductor manufacturing process or a display manufacturing process, the joined component being formed by joining at least two parent members by friction stir welding, and comprising:
multiple hollow channels formed inside the joined component and each which includes a temperature control means; and
at least two holes formed between each of the hollow channels by vertically passing through the parent members, and providing passages through which the process fluid passes,
wherein the holes are arranged in a spaced apart relationship at an interval of equal to or greater than 3 mm to equal to or less than 15 mm, and
a weld zone by friction stir welding is formed to remove at least a part of a horizontal interface between each of the hollow channels and each of the holes.
